(19) United States
(12) Patent Application Publication
(10) Pub. No.: US 2026/0181908 A1
(43) Pub. Date: Jun. 25, 2026

(54) SEMICONDUCTOR DEVICE INCLUDING FERROELECTRIC CAPACITOR

(71) Applicant: Samsung Electronics Co., Ltd., Suwon-si (KR)

(72) Inventors: Keonhee Park, Suwon-si (KR); Changyoung Lee, Suwon-si (KR); Moonyoung Jung, Suwon-si (KR); Haewook Jeong, Suwon-si (KR)

(21) Appl. No.: 19/430,180

(22) Filed: Dec. 22, 2025

(30) Foreign Application Priority Data
Dec. 23, 2024 (KR) 10-2024-0194705

(51) Int. Cl. H10B 53/20; H10B 53/30

(52) U.S. Cl. CPC H10B 53/20; H10B 53/30

(57) ABSTRACT

A semiconductor device includes a transistor structure and a capacitor structure connected to the transistor structure. The capacitor structure includes a plate line extending in a first direction, a ferroelectric capacitor connected to the plate line, a global plate line provided at the same level as the plate line, and a plate line select transistor connected to the global plate line and the plate line. The transistor structure includes an access transistor having a gate connected to a wordline, and one end connected to the ferroelectric capacitor and another end connected to a bitline.

### CROSS-REFERENCE TO RELATED APPLICATION(S)

This U.S. non-provisional application claims priority under 35 USC § 119 to Korean Patent Application No. 10-2024-0194705, filed on Dec. 23, 2024, in the Korean Intellectual Property Office, the disclosure of which is herein incorporated by reference in its entirety.

### BACKGROUND

Ferroelectric random access memory (FRAM) devices are being studied as one of the non-volatile memory devices that are configured to maintain data even when power is removed. FRAM has a simpler structure than dynamic random access memory (DRAM), but may be implemented as a non-volatile memory device with high density like a flash memory device. FRAMs with three-dimensionally stacked structures may be developed to implement high density.

### SUMMARY

In some examples, to overcome the scaling limit in a three-dimensional memory structure, a ‘1TnC’ structure FRAM may be developed. ‘1TnC’ refers to a form in which one access transistor ‘1T’ and ‘n’ ferroelectric capacitors ‘nC’ form one memory cell unit. However, in order to implement a ‘1TnC’ structure FRAM cell array in a three-dimensional structure, an excessively large number of plate line pads or contact plugs may be required compared to the cell area. Therefore, a technology that reduces the number of plate line pads may be explored in the implementation of 3D FRAM devices.

Implementations of the present disclosure provide a three-dimensional ferroelectric memory device with a reduced number of plate line pads and a method of manufacturing the same.

An aspect of the present disclosure provides a semiconductor device including a transistor structure and a capacitor structure connected to the transistor structure. The capacitor structure may include a plate line extending in a first direction, a ferroelectric capacitor connected to the plate line, a global plate line provided at the same level as the plate line, and a plate line select transistor connected to the global plate line and the plate line. The transistor structure may include an access transistor having a gate connected to a wordline, and one end connected to the ferroelectric capacitor and another end connected to a bitline.

Another aspect of the present disclosure provides a capacitor structure including a plate line, a ferroelectric capacitor connected to the plate line, a global plate line provided at the same level as the plate line, and a plate line select transistor connected to the global plate line and the plate line.

Another aspect of the present disclosure provides a semiconductor device including a cell array including a plurality of memory cells, respectively disposed at intersections of wordlines and bitlines, and an address decoder configured to transmit wordline signals and global plate line signals to the wordlines and a plurality of global plate lines. Each of the plurality of memory cells may include plate lines, ferroelectric capacitors connected to the plate lines, an access transistor having a gate connected to a corresponding one of the wordlines and one end connected to a corresponding one of the ferroelectric capacitors and another end connected to a corresponding one of the bitlines, the global plate line, and a plate line select transistor connecting the global plate line and the plate line.

### BRIEF DESCRIPTION OF DRAWINGS

FIG. 1 is a diagram illustrating a manufacturing process of an example of a ferroelectric memory device.

FIG. 2 is a cross-sectional view illustrating an example of a ferroelectric memory device.

FIG. 3 is a block diagram illustrating an example of a ferroelectric memory device.

FIG. 4 is a cross-sectional view and an equivalent circuit diagram illustrating a memory cell MC of the 1TnC structure of FIG. 3.

FIG. 5 is a circuit diagram illustrating an example structure of a three-dimensional array in which memory cells of the 1TnC structure are formed in a global plate line structure.

FIG. 6 is a circuit diagram briefly illustrating an example of applying a global plate line GPL to one memory cell MC.

FIG. 7 is a diagram illustrating the characteristics of an example of a ferroelectric capacitor.

FIG. 8 is a drawing illustrating an example of a write operation of an example of a ferroelectric memory cell.

FIG. 9 is a drawing illustrating an example of a read operation of an example of a ferroelectric capacitor.

FIG. 10 is a waveform diagram briefly illustrating an example of read and re-write operations in an example of a global plate line structure.

FIG. 11 is a diagram illustrating an arrangement structure of an example of a plate line contact plug.

FIG. 12 is a diagram illustrating an arrangement structure of an example of a plate line contact plug.

FIG. 13 is a diagram illustrating an arrangement structure of an example of a plate line contact plug.

FIG. 14 is a diagram illustrating an arrangement structure of an example of a plate line contact plug.

FIG. 15 is a circuit diagram illustrating an example of applying a global plate line to a single memory cell.

FIG. 16 is a perspective view illustrating a portion of the semiconductor corresponding to the circuit diagram of FIG. 15.

FIGS. 17A, 17B, and 17C are cross-sectional views taken along lines A1-A1′, B1-B1′, and C1-C1′ of FIG. 16.

FIGS. 18A, 18B, 18C, 18D, 18E, 18F, 18G, 18H, 18I, 18J, 18K, 18L, 18M, and 18N are cross-sectional views, sequentially illustrating a method of manufacturing the semiconductor device illustrated in FIG. 16.

FIG. 19 is a perspective view illustrating an example of a semiconductor device.

FIG. 20 is a perspective view illustrating an example of a semiconductor device.

FIG. 21 is a perspective view illustrating a semiconductor device corresponding to the circuit diagram of FIG. 15.

FIGS. 22A, 22B, and 22C are cross-sectional views taken along lines A2-A2′, B1-B1′, and C1-C1′ of FIG. 16.

FIGS. 23A, 23B, 23C, 23D, 23E, 23F, 23G, and 23H are cross-sectional views, sequentially illustrating a method of manufacturing a semiconductor device, taken along line A2-A2′ of FIG. 21.

FIGS. 24A, 24B, 24C, 24D, 24E, 24F, 24G, and 24H are cross-sectional views, sequentially illustrating a method of manufacturing a semiconductor device, taken along line B1-B1′ of FIG. 21.

FIGS. 25A, 25B, 25C, 25D, 25E, 25F, 25G, and 25H are cross-sectional views, sequentially illustrating a method of manufacturing a semiconductor device, taken along line C1-C1′ of FIG. 21.

FIG. 26 is a perspective view illustrating examples of semiconductor devices.

FIG. 27 is a perspective view illustrating examples of semiconductor devices.

### DETAILED DESCRIPTION

It is to be understood that both the foregoing general description and the following detailed description are examples, and it is to be considered that an additional description of the present disclosure is provided. Reference signs are indicated in detail in example implementations of the present disclosure, examples of which are indicated in the reference drawings. Wherever possible, the same reference numbers are used in the description and drawings to refer to the same or like parts; in such cases a repeated description related thereto may be omitted for brevity.

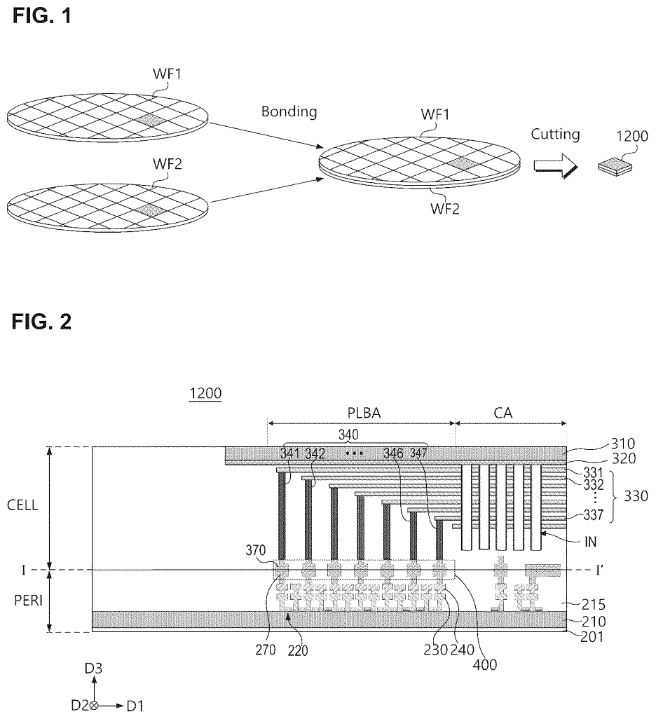

FIG. 1 is a drawing illustrating a manufacturing process of a ferroelectric memory device according to at least some implementations of the present disclosure. Referring to FIG. 1, a ferroelectric memory device 1200 may be formed as a stacked semiconductor memory by applying a wafer bonding method.

Integrated circuits are formed on each of the first wafer WF1 and the second wafer WF2. For example, a cell array may be formed on the first wafer WF1, and a peripheral circuit (configured to control the cell array) may be formed on the second wafer WF2. The peripheral circuit may include a voltage generator, a decoder, a control circuit, etc.

The first wafer WF1 and the second wafer WF2 are bonded using a hybrid bonding method. That is, the metals (e.g., copper) of each of the first wafer WF1 and the second wafer WF2 are bonded to each other, and the dielectrics (e.g., oxide layers) of each of the first wafer WF1 and the second wafer WF2 are bonded to each other. The surfaces of the first wafer WF1 and the second wafer WF2 are processed through a flattening and cleaning process for bonding. Then, the dielectrics are bonded by being pressurized under low pressure conditions. Finally, the metals filled in the upper and lower via holes are bonded through heat treatment.

The bonded wafers WF1 and WF2 are cut into a plurality of chips. Then, each of the cut chips is provided as a stacked ferroelectric memory device 1200 in which upper and lower semiconductor dies are bonded.

FIG. 2 is a cross-sectional view illustrating a ferroelectric memory device according to at least some implementations of the present disclosure. Referring to FIG. 2, the ferroelectric memory device 1200 has a chip-to-chip (C2C) structure. In order to form a ferroelectric memory device 1200 with the C2C structure, an upper chip including a cell part CELL is manufactured on a first wafer, and a lower chip including a peripheral circuit part PERI is manufactured on a second wafer different from the first wafer. Thereafter, a ferroelectric memory device 1200 with the C2C structure is formed by bonding the upper chip and the lower chip at a bonding surface (I-I′).

The peripheral circuit part PERI may include a first substrate 210, an interlayer insulating layer 215, a plurality of circuit elements 220 formed on the first substrate 210, a first metal layer 230 connected to each of the plurality of circuit elements 220, and a second metal layer 240 formed on the first metal layer 230. In some implementations, the first metal layer 230 may be formed of a first metal (e.g., tungsten) having relatively high resistance, and the second metal layer 240 may be formed of a second metal (e.g., copper) having relatively low resistance. However, the types of materials of the first metal layer 230 and the second metal layer 240 are not limited to the disclosure herein.

The interlayer insulating layer 215 is disposed on the first substrate 210 to cover the plurality of circuit elements 220, the first metal layer 230, and the second metal layer 240, and may include an insulating material such as silicon oxide, silicon nitride, a combination thereof, and/or the like. A lower bonding metal 270 may be formed on the second metal layer 240 of the plate line bonding area PLBA. In the plate line bonding area PLBA, the lower bonding metal 270 of the peripheral circuit part PERI may be electrically connected to the upper bonding metal 370 of the cell part CELL by a bonding method, and the lower bonding metal 270 and the upper bonding metal 370 may include aluminum, copper, tungsten, a combination thereof, and/or the like.

The cell part CELL may include a second substrate 310 and a base layer 320 on which an access transistor is formed. On the second substrate 310, a plurality of plate lines 330 (e.g., 331, 332, 333, 334, 335, 336, 337) may be laminated along a third direction D3 perpendicular to the upper surface of the second substrate 310.

In the plate line bonding area PLBA, the inner node IN may extend in a direction perpendicular to the upper surface of the second substrate 310 and penetrate through the plate lines 330. The inner node IN may include a ferroelectric layer, a channel layer, etc. In the plate line bonding area PLBA, the plate lines 330 may extend along a first direction D1 parallel to the upper surface of the second substrate 310 and may be connected to a plurality of contact plugs 340 (e.g., 341, 342, 343, 344, 345, 346, 347). The plate lines 330 and the contact plugs 340 may be connected to each other at pads provided by extending at least some of the plate lines 330 with different lengths along the first direction D1. The contact plugs 340 connected to the plate lines 330 may be connected to the peripheral circuit part PERI through the upper bonding metal 370 of the cell part CELL and the lower bonding metal 270 of the peripheral circuit part PERI in the plate line bonding area PLBA. In some implementations, one or more metal layers may be formed between the lower bonding metal 270 and upper bonding metal 370 of the contact plugs 340.

The contact plugs 340 transmit the plate line voltage VPL to each of the plate lines 330. The contact plugs 340 may also be referred to as plate line pads may be configured to provide an electrical connection with the outside of the chip. For example, the plate line voltage VPL is transmitted to the contact plugs 340 and the plate lines 330 via the lower bonding metal 270 and the upper bonding metal 370 connected to the upper portions of the first metal layer 230 and the second metal layer 240. Here, the bonds in which the lower bonding metal 270 and the upper bonding metal 370 are combined are referred to as plate line bonding 400. The plate line bonding 400 for providing the plate line voltage VPL to each of the plate lines 330 is formed by the lower bonding metal 270 and the upper bonding metal 370.

The contact plugs 340 or pads for connecting the upper bonding metal 370 and the plate lines 330 occupy a relatively large areas and resources. And, in order to form the three-dimensional FRAM of the ‘1TnC’ structure, there occurs a problem that the number of contact plugs 340 actually increases excessively. In some examples, a global plate line method and a wordline structure are provided that may be used to reduce the number of contact pads or contact plugs 340 in the three-dimensional FRAM of the ‘1TnC’ structure.

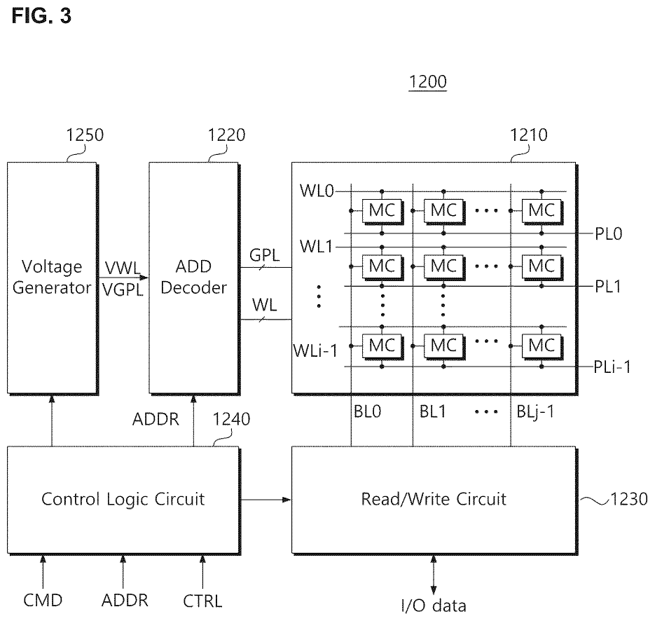

FIG. 3 is a block diagram illustrating a ferroelectric memory device according to some implementations of the present disclosure. Referring to FIG. 3, a ferroelectric memory device 1200 may include a cell array 1210, an address decoder 1220, a read/write circuit 1230, a control logic circuit 1240, and a voltage generator 1250.

The cell array 1210 may include a plurality of ferroelectric memory cells MCs. In these cases, the ferroelectric memory device 1200 may be referred to as FeRAM (Ferroelectric Random Access Memory) or FRAM. The plurality of ferroelectric memory cells MCs may be respectively arranged in areas where wordlines WL0 to WLi−1 and bitlines BL0 to BLj−1 intersect, and may form a matrix form. Each of the ferroelectric memory cells MCs may be connected to a corresponding wordline WL and a bitline BL. Meanwhile, each of the ferroelectric memory cells MCs may be connected to at least one plate line PL. At this time, at least one plate line PL may be arranged corresponding to each wordline WL, but is not limited thereto.

Each of the ferroelectric memory cells MCs may include an access transistor and at least one ferroelectric capacitor. At least one ferroelectric capacitor included in the ferroelectric memory cell MC may store and discharge a charge amount corresponding to data. According to some implementations, a plurality of ferroelectric memory cells MCs may store multi-bit data. At this time, depending on the implementation, one multi-bit data may be stored in one ferroelectric memory cell, or one multi-bit data may be stored in several ferroelectric memory cells. The ferroelectric memory cell(s) storing multi-bit data may be configured to store a charge amount corresponding to the multi-bit data by using ferroelectric capacitors included in the ferroelectric memory cell. And the charge amount stored in the ferroelectric capacitors may be discharged through a bitline connected to the ferroelectric memory cell.

In particular, the plate lines for configuring the cell array 1210 may be formed as a global plate line structure. Access to one memory cell MC is performed by turning on an access transistor AT by a wordline and activating the plate line. Therefore, in the global plate line structure of the present disclosure, the access transistor AT and the plate line select transistor PLST of all memory cells connected to the wordline may be turned on by the wordline signal VWL. The plate line select transistor PLST may transmit the global plate line signal VGPL to each plate line of the memory cell MC according to the wordline signal VWL. Finally, in the cell array 1210 of the global plate line structure, activation of one plate line may be achieved by a combination of a global plate line signal VGPL and a wordline signal VWL. This structure will be described in more detail through the drawings described below.

The address decoder 1220 is configured to select either a wordline of the cell array 1210 or a global plate line GPL in response to an address ADDR. The address decoder 1220 transmits a wordline signal VWL to a wordline of a selected memory area or memory cell. During a read or write operation, the address decoder 1220 may provide a wordline signal VWL and a global plate line signal VGPL to select a memory cell or a plate line. The access transistor AT of the memory cell MC selected by the wordline signal VWL is turned on. In addition, the plate line select transistors PLSTs of each of the memory cells connected to the corresponding wordline are turned on by the wordline signal VWL. Then, the address decoder 1220 may activate the plate line of one of the memory cells by providing the global plate line signal VGPL to one selected one of the plurality of global plate lines.

The read/write circuit 1230 operates as a write driver or a sense amplifier for accessing the cell array 1210. The read/write circuit 1230 is configured to detect data stored in the memory cell MC. In particular, the read/write circuit 1230 may detect data stored in the memory cell MC by comparing the bitline voltage VBL according to the amount of charge released from the memory cell MC to the bitline BL with the reference voltage Vref. The data detected by the read/write circuit 1230 may be output to the outside of the ferroelectric memory device 1200. In addition, the read/write circuit 1230 may transmit write data input from the outside to the cell array 1210.

The control logic circuit 1240 is configured to control the read/write circuit 1230, the address decoder 1220, and the voltage generator 1250 in response to a command CMD transmitted from the outside. The control logic circuit 1240 may control the voltage generator 1250, the read/write circuit 1230, and the address decoder 1220 to perform write, read, and re-write operations on a selected memory cell according to the command CMD. To this end, the control logic circuit 1240 may include a command decoder that is configured to decode the command CMD received from an external device.

The voltage generator 1250 is configured to generate a wordline signal VWL to be supplied to the wordline WL and a global plate line signal VGPL to be supplied to the global plate line GPL under the control of the control logic circuit 1240. The voltage generator 1250 may also generate a bitline voltage VBL to be supplied to the bitline BL under the control of the control logic circuit 1240.

As described above, the ferroelectric memory device 1200 may include a cell array 1210 formed with a global plate line structure. Activation of any one plate line of a memory cell selected through the global plate line structure may be performed by a combination of the global plate line signal VGPL and the wordline signal VWL. Through this structure, the area occupied by contact plugs or pads for electrically connecting the plate lines to the peripheral circuit part (PERI, see FIG. 2) may be minimized.

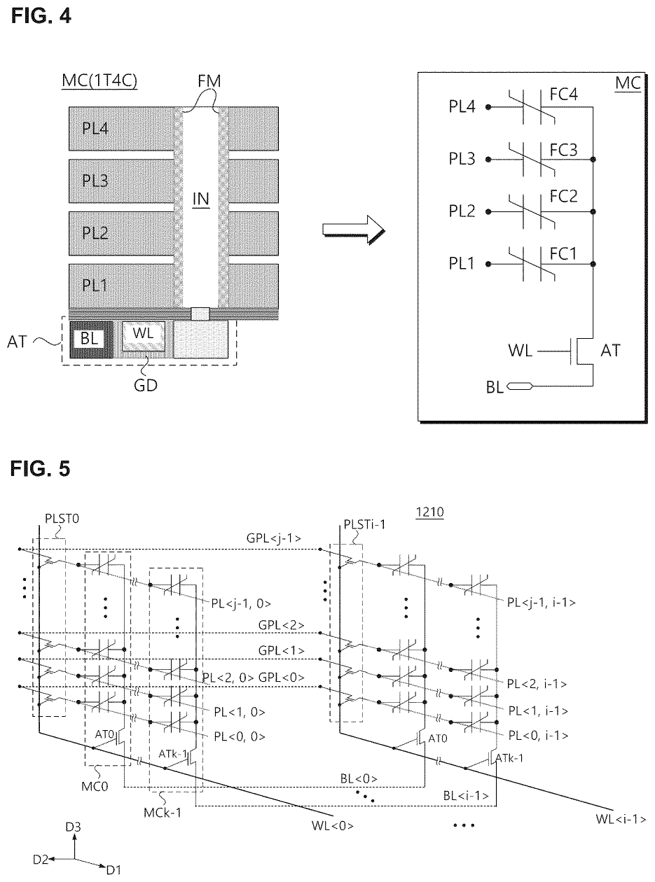

FIG. 4 is a cross-sectional view and an equivalent circuit diagram illustrating a memory cell MC of the 1TnC structure of FIG. 3. Referring to FIG. 4, a pillar or inner node IN is formed that penetrates throughplate lines PL1, PL2, PL3 and PL4 to form a memory cell MC. And a bitline BL and a wordline WL for forming an access transistor AT are formed at the bottom. Here, the structure of a memory cell MC of the ‘1T4C’ structure in which one access transistor AT and four ferroelectric capacitors FC1 to FC4 are formed will be described as an example.

The inner node IN penetrates throughplate lines PL1, PL2, PL3 and PL4 and the insulating material therebetween and is connected to the drain of the access transistor AT. As a result, the inner node IN may be considered to form the drain of the access transistor AT. A ferroelectric material FM is formed on the outer surface of the cylindrical inner node IN. The ferroelectric material FM may store data by polarization. The polarization state may be switched by an electric field formed between the inner node IN and the plate lines PL1, PL2, PL3 and PL4. The access transistor AT connects the bitline BL to the inner node IN according to the wordline signal VWL transmitted to the wordline WL. A gate electrode GD may be formed around the wordline WL to form the access transistor AT.

A memory cell MC of the ‘1T4C’ structure is formed as illustrated in the equivalent circuit by the structure described above. And in order to activate one ferroelectric capacitor FCk, the access transistor AT must be turned on by the wordline WL, and a plate line signal must be applied to one of the plate lines PL1, PL2, PL3 and PL4. In the case of the illustrated memory cell MC, the channel of the access transistor AT is formed as a two-dimensional transistor parallel to the substrate. However, the channel of the access transistor AT may be implemented as a transistor perpendicular to the substrate (e.g., vertical channel transistor). In these cases, the bitline BL may be located below the wordline WL.

Each of the ferroelectric capacitors FCk may include a ferroelectric material. The ferroelectric material may include at least one of lead zirconate titanate (PZT), strontium bismuth tantalate (SBT), and/or bismuth lanthanum titanate (BLT). In addition, the ferroelectric capacitor FCk may include, for example, at least one of hafnium oxide, hafnium zirconium oxide, zirconium oxide, barium strontium titanium oxide, barium titanium oxide, lead zirconium titanium oxide, or combinations thereof. Here, the hafnium zirconium oxide may be a material in which zirconium (Zr) is doped into hafnium oxide, or may be a compound of hafnium (Hf), zirconium (Zr), and oxygen (O). Each of the ferroelectric capacitors FCk may further include a doping element doped into the above-described material. The doping element may be an element selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), tin (Sn), a combination thereof, and/or the like.

In the above, the memory cell MC structure of the ‘1T4C’ structure has been briefly described. However, the circuit structure of the illustrated memory cell MC structure is a simplified structure for convenience of explanation, and the actual memory block is not limited to the illustrated example. That is, it will be well understood that one memory cell MC may include more ferroelectric capacitors.

FIG. 5 is a circuit diagram illustrating the structure of a three-dimensional array in which memory cells of the ‘1TnC’ structure are formed in a global plate line structure. Referring to FIG. 5, the cell array 1210 shares the same global plate line GPL<k> with the ferroelectric capacitors of the same layer. And the access transistors ATs of the memory cells connected to the corresponding wordline by one wordline WL and the plate line select transistors PLST for connecting the plate line of each layer and the global plate line are turned on simultaneously. Therefore, the contact plugs (340, see FIG. 2) or pads that must be formed for driving the plate lines may be formed only as many as the number of global plate lines GPL.

A plurality of memory cells MC0 to MCk−1 may be connected to the wordline WL<0>. The access transistors AT0 to ATk−1 of each of the plurality of memory cells MC0 to MCk−1 may be turned on or off by the wordline signal VWL supplied to the wordline WL<0>. Each of the memory cells MC0˜MCk−1 may be connected to the corresponding bitline BL<0> to BL<i−1> only when the access transistors AT0˜ATk−1 are turned on.

The plate line select transistors PLST0 are turned on or off according to the wordline signal VWL supplied from the wordline WL<0>. The plate line select transistors PLST0 are configured to connect or disconnect (or block) the global plate lines GPL<0> to GPL<j−1> to the plate lines PL<0> to PL<j−1> of the same layer based on activation. For example, if the plate line select transistors PLST0 are turned on by the wordline signal VWL supplied to the wordline WL<0>, the global plate lines GPL<0> to GPL<j−1> are connected to the plate lines PL<0, 0> to PL<j−1, 0> of the memory cells MC0 to MCk−1, respectively. Therefore, the activation of the ferroelectric capacitor of the selected memory cell depends on the global plate line signal VGPL applied to each of the global plate lines GPL<0> to GPL<j−1>. As such, contact plugs or pads do not need to be formed for all of the plate lines for the activation of the ferroelectric capacitor of each of the memory cells. Only the contact plugs or pads may be formed for each of the global plate lines GPL<0> to GPL<j−1>. That is, the contact plugs or pads may be formed only as many as the number of stacked plate lines. Therefore, the chip area for the contact plug or pad may be minimized.

Each of the wordlines WL<0> to WL<i−1> must simultaneously control the access transistor AT of each of the memory cells and the plate line select transistor PLST of each layer. Therefore, each of the wordlines WL<0> to WL<i−1> extending in the horizontal direction D1 may be extended by changing the direction in the vertical direction D3. That is, each of the wordlines WL<0> to WL<i−1> may be formed in the shape of the alphabet ‘L’. Each of the wordlines WL<0> to WL<i−1> in the horizontal direction D1 may form common gate of access transistors AT0 to ATk−1, and each of the wordlines WL<0> to WL<i−1> in the vertical direction D3 may form common gate of each of the plate line select transistors PLST0 to PLSTi−1.

According to the cell array 1210 of the global plate line structure of the present disclosure illustrated, the plate lines of each layer may share the global plate line GPL of the same layer. In addition, each of the wordlines WL<0> to WL<i−1> may turn on the plate line select transistor PLST simultaneously with the access transistors AT of the connected memory cells. Therefore, a contact plug or pad for activating the plate line may be formed only on the global plate line GPL.

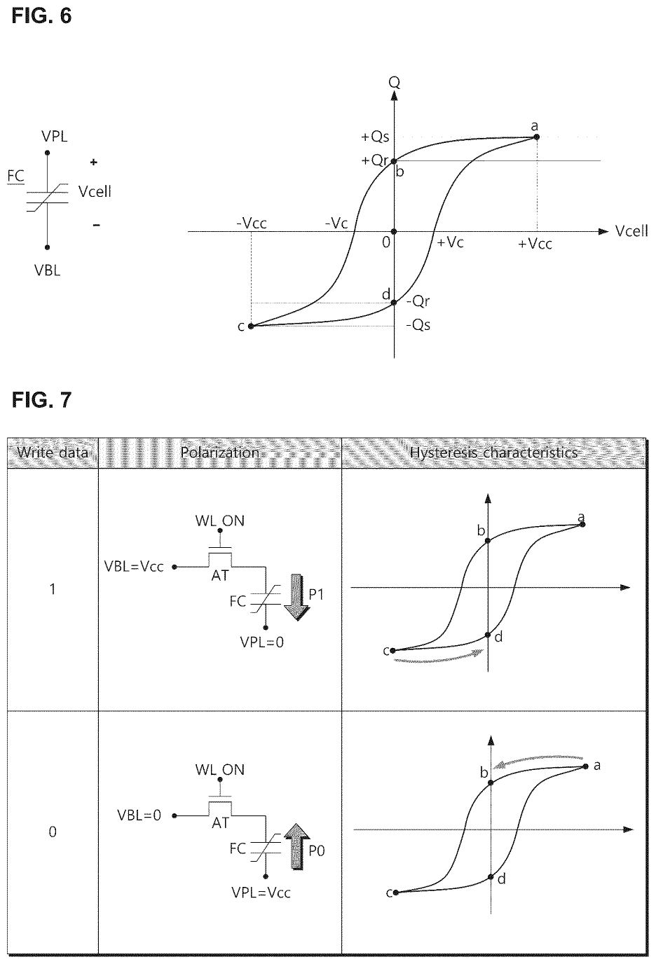

FIG. 6 is a drawing illustrating the hysteresis characteristic of the ferroelectric capacitor of the present disclosure. Referring to FIG. 7, the ferroelectric capacitor FC exhibits a hysteresis loop characteristic for the cell voltage Vcell applied to both ends.

The horizontal axis of the cell characteristic graph represents the cell voltage Vcell applied to both ends of the ferroelectric capacitor FC, and the vertical axis represents the total charge Q or polarization induced on the surface of the ferroelectric capacitor FC according to the cell voltage Vcell. In addition, ‘Qr’ represents the remnant charge, ‘Qs’ represents the saturation charge, and ‘Vc’ represents the coercive voltage, respectively. The coercive voltage Vc represents the voltage size that makes the total charge of the ferroelectric capacitor FC ‘0’. Meanwhile, ‘VPL’ and ‘VBL’ indicated on both ends of the ferroelectric capacitor FC represent the voltage applied through the plate line PL and the voltage applied through the bitline BL, respectively.

When the cell voltage Vcell increases from ‘0’ to the positive direction, polarization occurs in the ferroelectric material of the ferroelectric capacitor FC, and the total charge Q of the ferroelectric capacitor FC increases. When the cell voltage Vcell becomes a positive saturation voltage +Vcc, the total charge Q reaches the ‘a’ point corresponding to the saturation charge +Qs. At this time, even if the cell voltage Vcell increases further, the total charge Q does not increase any further. In other words, the ferroelectric capacitor FC enters a saturation polarization state when the cell voltage Vcell is greater than the positive saturation voltage +Vcc. After that, even if the cell voltage Vcell decreases to ‘0’ again, the polarization direction is maintained. Therefore, the total charge Q moves along the curve and reaches the ‘b’ point, which is a non-zero residual charge +Qr.

When the cell voltage Vcell increases in the negative direction when the total charge Q is the residual charge (+Qr, point ‘b’), the total charge Q moves along the curve from point ‘b’, passes 0, and becomes the negative saturation charge (−Qs, point ‘c’). Even if the cell voltage Vcell increases in the negative direction more than the negative saturation voltage −Vcc, the total charge Q does not increase in the negative direction any further. That is, the ferroelectric capacitor FC enters a saturation polarization state even when the cell voltage Vcell is lower than the negative saturation voltage −Vcc. At this time, the polarization direction of the ferroelectric material of the ferroelectric capacitor FC becomes the opposite to that at point ‘a’. After that, even if the cell voltage Vcell becomes ‘0’ again, the polarization direction is maintained, and the total charge Q moves along the curve and becomes a negative residual charge (−Qr, ‘d’ point) that is not ‘0’. On the other hand, if the cell voltage Vcell is increased in the positive direction again at the ‘d’ point, the total charge moves along the curve from the ‘d’ point, passes 0, and changes to the ‘a’ point.

According to the above, when a cell voltage Vcell having a positive saturation voltage +Vcc or a negative saturation voltage −Vcc is applied to both ends of a ferroelectric capacitor FC, the polarization direction according to spontaneous polarization is maintained even if the applied voltage is removed. The surface charge of the ferroelectric material due to spontaneous polarization is not naturally lost due to leakage, etc. If a coercive voltage (+Vc or −Vc) is not applied so that the polarization degree becomes ‘0’, the polarization direction is maintained as is.

According to some implementations, a state in which a positive saturation voltage +Vcc is applied to both terminals of a ferroelectric capacitor FC and then removed, (e.g., a state in which the total charge Q is a positive residual charge (+Qr, ‘b’ point)) may correspond to a state in which data ‘0’ is stored in the ferroelectric capacitor FC. In addition, a state in which a negative saturation voltage −Vcc is applied to both terminals of the ferroelectric capacitor FC and then removed (e.g., a state in which the total charge Q is a negative residual charge (−Qr, ‘d’ point)) may correspond to a state in which data ‘l’ is stored in the ferroelectric capacitor FC. However, the logical value of the data to be stored is not limited to the disclosure herein.

FIG. 7 is a drawing explaining a write operation of a ferroelectric memory cell according to some implementations of the present disclosure. Referring to FIG. 7, saturation polarization in different directions occurs in the ferroelectric capacitor FC depending on the data being written.

In the write operation of data ‘l’, a wordline signal VWL for turning on the access transistor AT is applied to the wordline WL. Then, a saturation voltage Vcc is applied to the bitline BL and 0 V is applied to the plate line PL. Then, the cell voltage Vcell at both ends of the ferroelectric capacitor FC becomes a negative saturation voltage −Vcc. At this time, saturation polarization in the ‘P1’ direction occurs in the ferroelectric capacitor FC. And the total charge Q of the ferroelectric capacitor FC is located at the ‘c’ point. Afterwards, even if the cell voltage Vcell is removed, the polarization direction is maintained, and the total charge Q moves to the ‘d’ point. In this way, data ‘l’ may be written to the ferroelectric capacitor FC.

During the write operation of data ‘0’, the wordline signal VWL is applied to the wordline WL to turn on the access transistor AT. Then, 0 Vis applied to the bitline BL and a positive saturation voltage +Vcc is applied to the plate line PL. Then, the cell voltage Vcell at both ends of the ferroelectric capacitor FC becomes a positive saturation voltage +Vcc. At this time, saturation polarization in the ‘P0’ direction occurs in the ferroelectric capacitor FC, and the total charge Q of the ferroelectric capacitor FC is located at the ‘a’ point. After that, even if the cell voltage Vcell is removed, the polarization direction is maintained, and the total charge moves to the ‘b’ point. As described above, writing of data ‘0’ to the ferroelectric capacitor FC is performed.

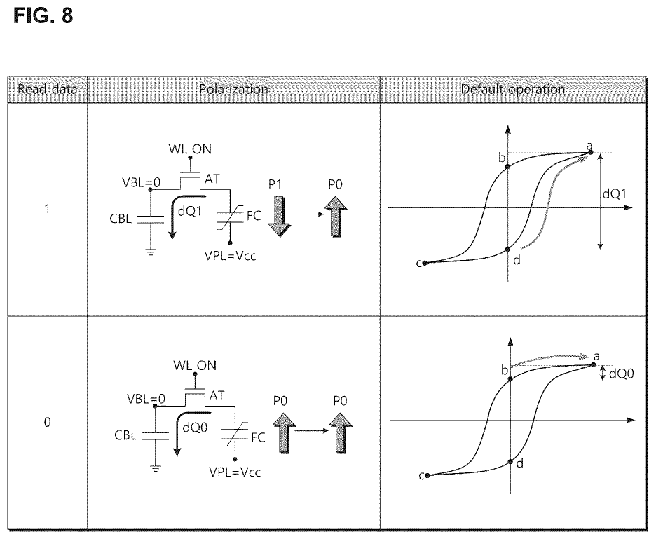

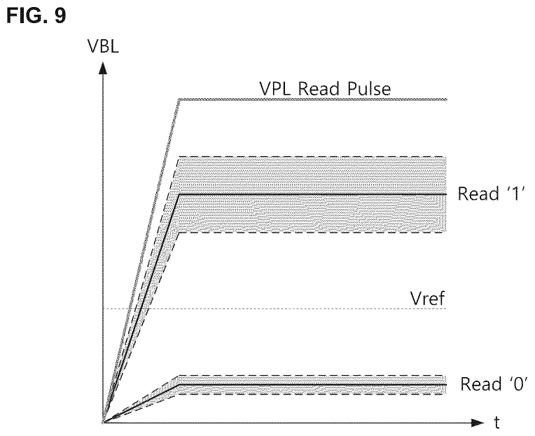

FIG. 8 is a drawing explaining a read operation of the ferroelectric capacitor of the present disclosure. Referring to FIG. 9, when reading data stored in the ferroelectric capacitor FC, a plate line voltage VPL at the saturation voltage Vcc level is provided to the plate line PL. Then, a wordline signal VWL for turning on the access transistor AT is applied to the gate of the access transistor AT. In this state, the polarization direction of the ferroelectric capacitor FC may be switched or maintained depending on the stored data.

During the read operation, a voltage of the same level as the voltage for writing data ‘0’ may be applied to both ends of the ferroelectric capacitor FC. For example, during the read operation, the bitline BL may be pre-charged to 0 V, and a saturation voltage Vcc may be applied to the plate line PL. In this case, the polarization direction of the ferroelectric capacitor FC may be switched or maintained depending on the type of stored data. When the polarization direction is switched, a relatively large amount of charge is discharged from the ferroelectric capacitor FC to the bitline BL. On the other hand, when the polarization direction is maintained, a relatively small amount of charge is be discharged from the ferroelectric capacitor FC to the bitline BL. Based on the difference in the amount of charge discharged to the bitline BL, the sense amplifier of the read/write circuit 1230 may identify the data.

When data ‘1’ is stored in the ferroelectric capacitor FC, the total charge Q of the ferroelectric capacitor FC is located at the ‘d’ point, and the polarization direction corresponds to ‘P1’. At this time, a wordline signal VWL is applied to turn on the access transistor AT to the wordline WL, and the bitline BL is pre-charged to zero volts (0 V). Then, when the saturation voltage Vcc is applied to the plate line PL, the polarization direction is switched to ‘P0’. Then, the total charge amount Q of the ferroelectric capacitor FC moves from the ‘d’ point to the ‘a’ point. In this case, the charge amount dQ1 corresponding to the difference between the ‘d’ point and the ‘a’ point may be released to the bitline BL through the access transistor AT.

In the state where data ‘0’ is stored, the total charge amount of the ferroelectric capacitor FC is located at the ‘b’ point, and the polarization direction corresponds to ‘P0’. At this time, a wordline signal VWL for turning on the access transistor AT is applied to the wordline WL, and the bitline BL is pre-charged to 0 V. Then, when the saturation voltage Vcc is applied to the plate line PL, the total charge Q of the ferroelectric capacitor FC moves from the ‘b’ point to the ‘a’ point. In this case, the polarization direction is maintained as it is, and the charge amount dQ0 corresponding to the difference between the ‘b’ point and the ‘a’ point may be released to the bitline BL through the access transistor AT.

Since the bitline BL has a capacitance component CBL, when the charge amount is released to the bitline BL, the bitline voltage VBL corresponding to the released charge amount may be applied to the bitline BL. At this time, the level of the bitline voltage VBL may be proportional to the level of the charge amount released to the bitline BL. Therefore, the sense amplifier may determine the type of data stored in the ferroelectric capacitor FC by comparing the bitline voltage VBL and the reference voltage Vref.

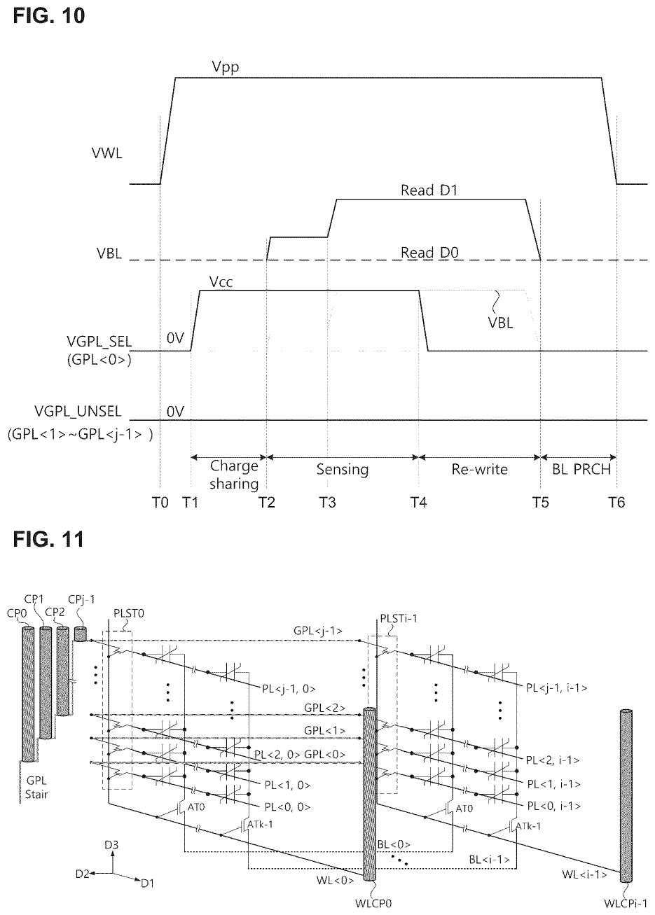

FIG. 9 is a graph illustrating a sensing method through a bitline voltage VBL according to the discharge of charge to a bitline of a ferroelectric capacitor FC during a read operation. Referring to FIG. 10, the amount of charge discharged to a bitline BL during the read operation varies depending on the data stored in the ferroelectric capacitor FC. The level of the bitline voltage VBL according to the amount of the discharged charge during the read operation is detected to identify the stored data.

When data ‘l’ is stored in the ferroelectric capacitor FC, a relatively large amount of charge, ‘dQ1’, will be discharged to the bitline BL. Therefore, a bitline voltage VBL higher than a reference voltage Vref may be set to the bitline BL. A sense amplifier may detect a bitline voltage VBL higher than a reference voltage Vref and identify it as data ‘1’. On the other hand, if data ‘0’ is stored in the ferroelectric capacitor FC, a relatively small charge amount ‘dQ0’ will be released to the bitline BL. Therefore, a bitline voltage VBL lower than the reference voltage Vref may be set to the bitline BL. A sense amplifier may detect the bitline voltage VBL lower than the reference voltage Vref and identify it as data ‘0’.

On the other hand, when data ‘1’ is detected, a bitline voltage VBL corresponding to data ‘1’ will be set on the bitline BL. Therefore, by lowering the voltage of the plate line PL to 0 V, data ‘1’ may be reprogrammed to the ferroelectric capacitor FC. This operation may be called a write back operation.

The above has explained the case where data is written or read to one ferroelectric capacitor FC. However, it will be well understood that data writing or reading operations may be performed for each of the plurality of ferroelectric capacitors in the above-described manner even in the ferroelectric memory cell of the ‘1TnC’ structure.

FIG. 10 is a waveform diagram briefly illustrating a read and re-write operation in a global plate line structure according to some implementations of the present disclosure. Referring to FIG. 5 and FIG. 11, a case in which global plate line GPL<0> are selected among a plurality of global plate lines GPL<0> to GPL<j−1> and a wordline WL<0> is selected will be described as an example.

At time T0, a wordline signal VWL is applied to a wordline WL<0> corresponding to a selected row. A relatively high voltage (for example, 3V) may be applied to the wordline signal VWL. By supplying the wordline signal VWL, the access transistors AT0 to ATk−1 whose gates are connected to the wordline WL<0> are turned on. In addition, the plate line select transistors PLSTs for each layer whose gates are connected to the wordline WL<0> will be turned on.

At time T1, the global plate line signal VGPL is applied to the selected global plate line GPL<0>. The global plate line signal VGPL may be provided at, for example, a saturation voltage Vcc level. On the other hand, 0 V will be provided to the unselected global plate lines GPL<1> to GPL<j−1>. By supplying the global plate line signal VGPL to the selected global plate line GPL<0>, a positive saturation voltage +Vcc is applied to both ends of the ferroelectric capacitor FC connected to the global plate line GPL<0> of the memory cell MC<0>.

At time T2, the ferroelectric capacitor FC will discharge a charge (‘dQ1’ or ‘dQ0’) proportional to the difference between the saturation polarization value at the positive saturation voltage +Vcc state and the previous state polarization value. In other words, charge sharing occurs.

At time T3, the sense amplifier of the read/write circuit 1230 amplifies the size of the bitline voltage VBL set by the discharge charge amount (‘dQ1’ or ‘dQ0’). The sense amplifier determines the data stored in the ferroelectric capacitor FC as ‘1’ or ‘0’ according to the level of the amplified bitline voltage VBL.

At time T4, when the global plate line signal VGPL supplied to the selected global plate line GPL<0> is blocked, rewriting of the ferroelectric capacitor FC begins. The negative saturation voltage-Vcc is applied again to both ends of the ferroelectric capacitor FC where data ‘l’ is read, and as a result, data ‘l’ is written again to the ferroelectric capacitor FC. On the other hand, in the case of the ferroelectric capacitor FC where data ‘0’ is read, since no data destruction occurs, the voltage at both ends of the ferroelectric capacitor FC is maintained at 0 V.

At time T5, the bitline pre-charge period BL PRCH following the re-write period begins. Afterwards, at time T6, when the wordline signal VWL is deactivated to a low level, the read and re-write operation sequence of the selected ferroelectric capacitor FC is terminated.

As described above, the selection of one ferroelectric capacitor FC of the memory cell may be selected through a combination of the wordline WL and the global plate line signal VGPL. Accordingly, the number of contact plugs or pads for each plate line may be significantly reduced.

FIG. 11 is a drawing showing the arrangement structure of a plate line contact plug according to the first implementation. Referring to FIG. 11, in the global plate line structure, pads or plate line contact plugs CP0 to CPj−1 for inter-chip bonding may be formed one by one for each of the global plate lines GPL<0> to GPL<j−1>. In addition, wordline contact plugs WLCP0 to WLCPi−1 corresponding to each of the wordlines WL<0> to WL<i−1> may be formed.

Plate lines (e.g., PL<1, 0> to PL<1, i−1>) located in the same layer are connected to one global plate line GPL<1> through plate line selection transistor (PLST0 to PLSTi−1). The access transistors AT0 to ATk−1 and the plate line selection transistor PLST0 corresponding to the row selected by the wordline (e.g., WL<0>) are all activated. Accordingly, in the cell array of the global plate line structure, the memory cell or the ferroelectric capacitor FC of the selected row may be selected through the combination of the wordline signal VWL and the global plate line signal VGPL.

Accordingly, the plate line voltage VPL application to the selected ferroelectric capacitor FC may be performed via the global plate lines GPL<0> to GPL<j−1>. That is, the plate line voltage VPL application to each ferroelectric capacitor FC of the cell array 1210 is performed in units of global plate lines GPL<0> to GPL<j−1> rather than individual plate lines (PL<0, 0> to PL<j−1, i−1>). Therefore, the contact plug or pad for transmitting the plate line voltage VPL may be formed in units of global plate lines GPL<0> to GPL<j−1>.

The global plate lines GPL<0> to GPL<j−1> may be formed in a staircase shape (e.g., GPL Stair) that does not overlap with different layers as illustrated. And by forming one plate line contact plug for each staircase, a C2C structure may be formed. In other words, one plate line contact plug CP0 may be formed in the global plate line GPL<0> shared by the plate lines PL<0, 0> to PL<0, i−1>. And one plate line contact plug CP1 may be formed in the global plate line GPL<1> connected to the plate lines PL<1, 0> to PL<1, i−1> so as not to overlap with the upper layer of the global plate line GPL<0>. One plate line contact plug CP2 may be formed on the global plate line GPL<2> connected to the plate lines PL<2, 0> to PL<2, i−1> so as not to overlap on the upper layer of the global plate line GPL<1>. In this way, plate line contact plugs CP0 to CPj−1 may be formed to correspond to the global plate lines GPL<0> to GPL<j−1>, respectively.

In addition, one of the corresponding wordline contact plugs WLCP0 to WLCPi−1 may be formed on the wordlines WL<0> to WL<i−1>.

According to the configuration of the plate line contact plugs CP0 to CPj−1 in the above-described global plate line structure, the number of plate line contact plugs for driving the plate line may be significantly reduced.

FIG. 13 is a drawing showing the arrangement structure of the plate line contact plug according to the second implementation. Referring to FIG. 13, in the global plate line structure, pads or plate line contact plugs CP0 to CPj−1 for inter-chip bonding may be formed one by one for each of the global plate lines GPL<0> to GPL<j−1>. And wordline contact plugs WLCP0 to WLCPi−1 corresponding to each of the wordlines WL<0> to WL<i−1> may be formed.

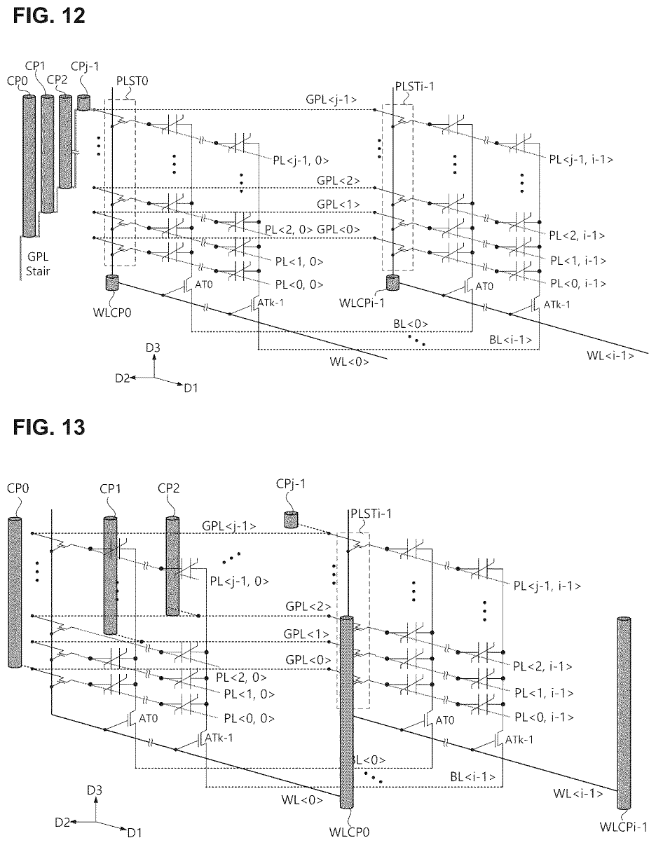

Unlike FIG. 12, the wordline contact plugs WLCP0 to WLCPi−1 may be formed on the same side in the D1 direction where the plate line contact plugs CP0 to CPj−1 are formed. That is, the wordline contact plugs WLCP0 to WLCPi−1 may be formed to connect the wordline and the pad in a lower layer than the layers where the plate line contact plugs CP0 to CPj−1 are formed. In particular, the wordline contact plugs WLCP0 to WLCPi−1 may be extended from the upper side of the gate side of the plate line selection transistor PLST0 to PLSTi−1 to each of the wordlines WL<0> to WL<i−1>.

According to the configuration of the plate line contact plugs CP0 to CPj−1 in the global plate line structure described above, the number of plate line contact plugs for driving the plate line may be drastically reduced.

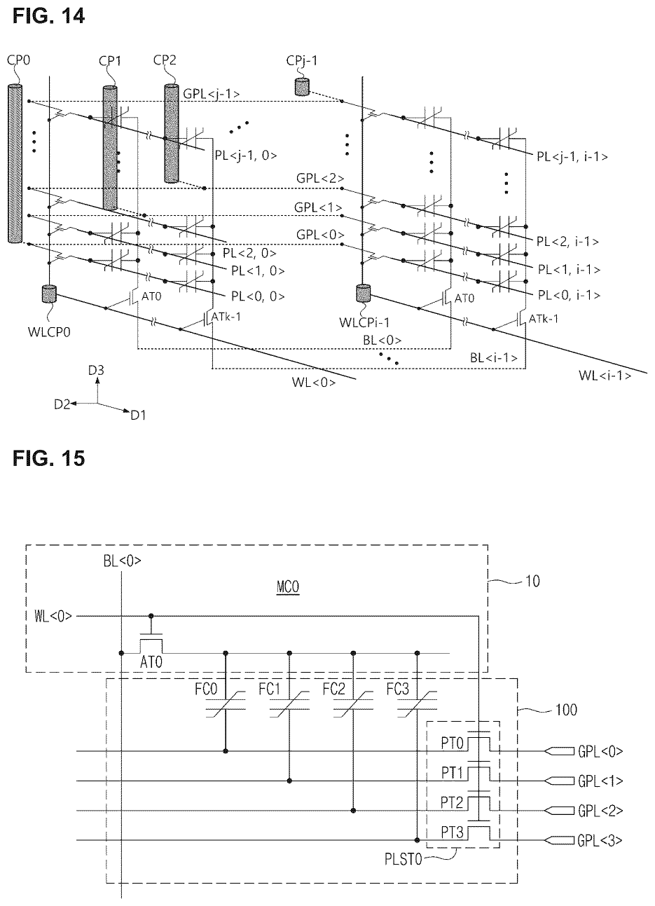

FIG. 14 is a drawing showing the arrangement structure of a plate line contact plug according to the third implementation. Referring to FIG. 14, in the global plate line structure, pads or plate line contact plugs CP0 to CPj−1 for inter-chip bonding may be formed one by one for each of the global plate lines GPL<0> to GPL<j−1>. In addition, wordline contact plugs WLCP0 to WLCPi−1 corresponding to each of the wordlines WL<0> to WL<i−1> may be formed. In particular, the plate line contact plugs CP0 to CPj−1 are connected to the global plate lines GPL<0> to GPL<j−1> formed in a step shape in the D2 direction. Therefore, there is no need to occupy an excessive chip area in the D1 direction in order to form the plate line contact plugs CP0 to CPj−1.

The global plate lines GPL<0>˜GPL<j−1> may be formed in a stair shape (e.g., GPL Stair) that does not overlap with other layers in a diagonal direction in the ‘D2×D3’ plane as illustrated. And since one plate line contact plug is formed for each stair, pads or bonding for C2C may be formed on top of the plate line contact plugs CP0 to CPj−1. In addition, wordline contact plugs WLCP0 to WLCPi−1 may be formed on the opposite side of the plate line contact plugs CP0 to CPj−1 centered on the cell array 1210 in the wordlines WL<0> to WL<i−1>.

According to the configuration of the plate line contact plugs CP0˜CPj−1 in the global plate line structure described above, the number of plate line contact plugs for driving the plate line may be drastically reduced.

FIG. 14 is a drawing showing the arrangement structure of a plate line contact plug according to the fourth implementation. Referring to FIG. 15, in the global plate line structure, pads or plate line contact plugs CP0 to CPj−1 for inter-chip bonding may be formed one by one for each of the global plate lines GPL<0> to GPL<j−1>. And wordline contact plugs WLCP0 to WLCPi−1 corresponding to each of the wordlines WL<0> to WL<i−1> may be formed. The plate line contact plugs CP0 to CPj−1 may be formed in substantially the same manner as those of FIG. 14 described above.

In particular, wordline contact plugs WLCP0 to WLCPi−1 may be formed on the same side as the plate line contact plugs CP0 to CPj−1 with respect to the cell array 1210 as the center of the wordlines WL<0> to WL<i−1>. That is, unlike FIG. 14, the wordline contact plugs WLCP0 to WLCPi−1 may be formed on the same side as the plate line contact plugs CP0 to CPj−1 in the D1 direction. In other words, the wordline contact plugs WLCP0 to WLCPi−1 may be formed to connect the wordline and the pad in a lower layer than the layers in which the plate line contact plugs CP0 to CPj−1 are formed. In addition, the wordline contact plugs WLCP0 to WLCPi−1 may be extended from the upper side of the gate side of the plate line selection transistor PLST0 to PLSTi−1 to each of the wordlines WL<0> to WL<i−1>.

FIG. 15 is a circuit diagram illustrating an example of applying a global plate line to one memory cell.

Referring to FIG. 15, a semiconductor device may include a first device part 10 and a second device part 100. The first device part 10 may include an access transistor AT0, and the second device part 100 may include plate line select transistors PLST0 and ferroelectric capacitors FC0, FC1, FC2, and FC3.

A gate of the access transistor AT0 is connected to a wordline WL<0>. One end of the access transistor AT0 is connected to a bitline BL<0>. The ferroelectric capacitors FC0, FC1, FC2, and FC3 may be formed between another end of the access transistor AT0 and each of the plate lines PL<0, 0>, PL<1, 0>, PL<2, 0>, and PL<3, 0>.

Each of the plate lines PL<0, 0>, PL<1, 0>, PL<2, 0>, and PL<3, 0> may be connected to each of the global plate lines GPL<0>, GPL<1>, GPL<2>, and GPL<3> by the plate line select transistors PLST0. For example, the plate line PL<0, 0> formed on the first layer is connected to the global plate line GPL<0> by a plate line select transistor PT0. The plate line PL<1, 0> formed on the second layer is connected to the global plate line GPL<1> by a plate line select transistor PT1. The plate line PL<2, 0> formed on the third layer is connected to the global plate line GPL<2> by a plate line select transistor PT2. The plate line PL<3, 0> formed on the fourth layer is connected to the global plate line GPL<3> by a plate line select transistor PT3. Each of the global plate lines GPL<0>, GPL<1>, GPL<2>, and GPL<3> is connected to all plate lines PL of a corresponding layer.

To select the ferroelectric capacitor FC3 for a read or write operation, a wordline signal VWL (see FIG. 3) may be applied to the wordline WL<0>, and a bitline voltage VBL (see FIG. 3) may be applied to the bitline BL<0>. The access transistor AT0 is turned on by the wordline signal VWL. The plate line select transistors PT0, PT1, PT2, and PT3 are also turned on simultaneously with the access transistor AT0 by the wordline signal VWL. A global plate line signal VGPL (see FIG. 3) may be provided to the global plate line GPL<3> through plate line contact plugs CP or pads to activate the plate line PL<3, 0>.

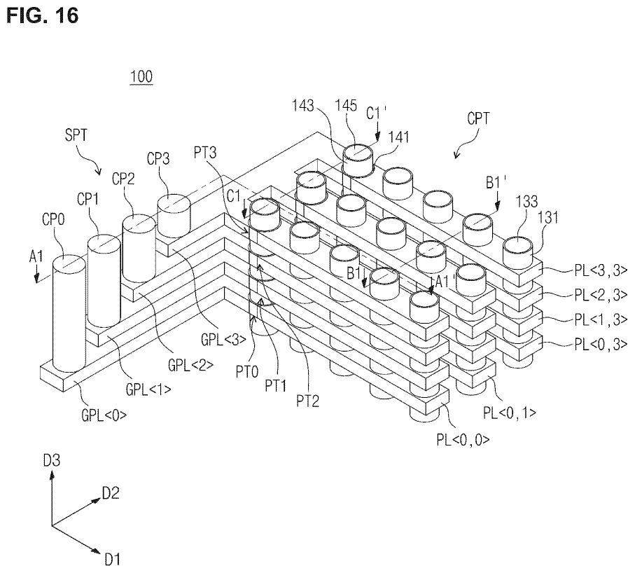

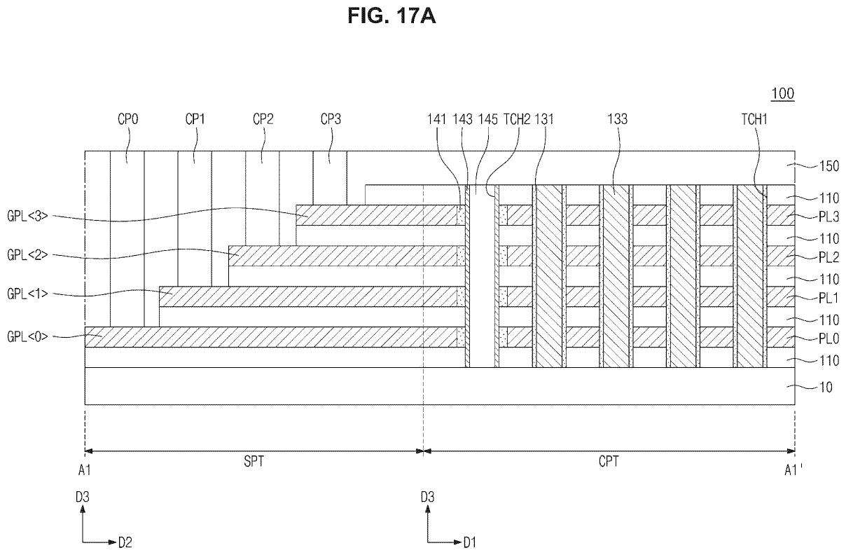

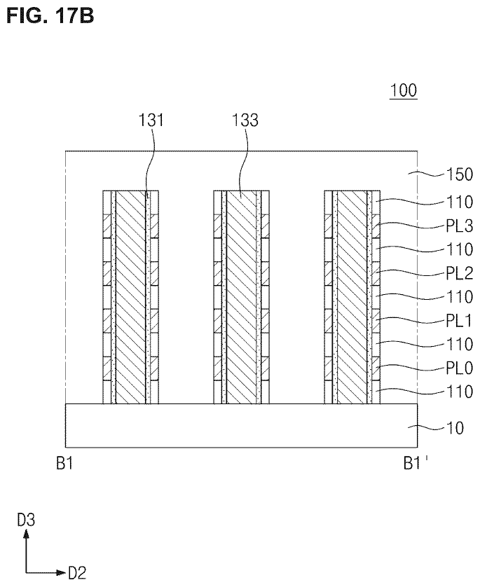

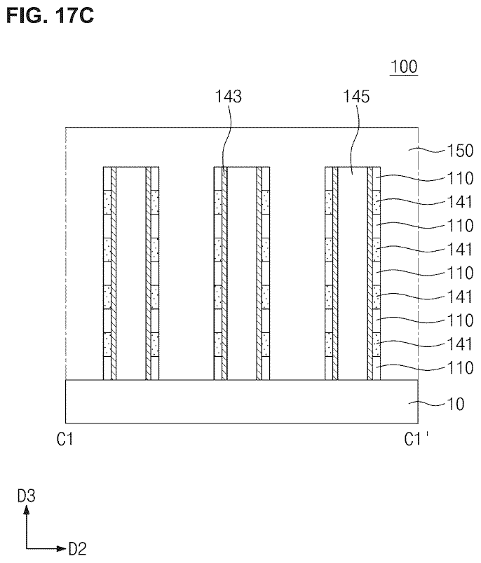

FIG. 16 is a perspective view illustrating a portion of the semiconductor corresponding to the circuit diagram of FIG. 15, and illustrates the second device part 100. FIGS. 17A, 17B, and 17C are cross-sectional views taken along lines A1-A1′, B1-B1′, and C1-C1′ of FIG. 16. FIGS. 16 and 17A to 17C illustrate the global plate lines GPL and the plate lines PL as an example corresponding to the arrangement structure of the plate line contact plugs CP of FIG. 11. In the following drawings, the numbers in the reference signs (e.g., <0>, <1>, <1, 0>, etc.) are used to indicate the connection and/or positional relationship or order of specific components. In addition, when referring to a specific component regardless of connection and/or positional relationship or order thereof, the reference sign may be used without the number.

In FIGS. 16 and 17A to 17C, four global plate lines GPL provided on four layers and three columns of plate lines PL corresponding to each global plate line GPL are illustrated as an example. For clarity, the mutually perpendicular X, Y, and Z-axis directions are illustrated as first to third directions D3 in FIGS. 16 and 17A to 17C, respectively.

Referring to FIGS. 15, 16, and 17A to 17C, a semiconductor device according to one or more implementations may include a capacitor structure and a transistor structure.

In the present implementation, the transistor structure corresponds to the first device part 10, and the capacitor structure 100 corresponds to the second device part 100. Therefore, for clarity, reference signs of the transistor structure and the capacitor structure 100 will be used as the same as the reference signs of the first device part 10 and the second device part 100.

The first device part 10 may include wordlines WL, bitlines BL, and access transistors. Each of the access transistors may be connected to a corresponding wordline WL among the wordlines WL and a corresponding bitline BL among the bitlines BL. A detailed description of the transistor structure 10 will be provided later.

A capacitor structure 100 may be provided on the transistor structure 10. For example, at least a portion of the capacitor structure 100 may vertically overlap the transistor structure 10. However, the arrangement relationship between the transistor structure 10 and the capacitor structure 100 is not limited thereto and may be different.

The capacitor structure 100 may include a capacitor region CPT and a staircase region SPT connected to the capacitor region CPT. The capacitor region CPT may be may be connected to the transistor structure 10, and may be a region in which charge is stored by forming a ferroelectric capacitor.

The capacitor region CPT may include ferroelectric capacitors and plate line select transistors PT.

The ferroelectric capacitors may be stacked in a third direction D3.

The ferroelectric capacitors may include plate lines PL, capacitor electrodes 133, and ferroelectric layers 131 provided between the plate lines PL and the capacitor electrodes 133.

In the capacitor region CPT, the plate lines PL may extend in a first direction D1 and may be spaced apart from each other in a second direction D2. In addition, the plate lines PL may be stacked in a multilayer structure in the third direction D3. The plate lines PL may be arranged in a matrix in the second direction D2 and the third direction D3. The second direction D2 may be a row direction, and the third direction D3 may be a column direction. In the drawings, plate lines PL provided in a 4×3 matrix are illustrated. For clarity, a portion of the plate lines PL are indicated with both row and column numbers or only with a row number. For example, “PL<0,1>” refers to a plate line in the second column of the first row, and “PL1” refers to a plate line in the second row.

In plan view, the plate lines PL may include a first side extending in the first direction D1 and a second side extending in the second direction D2. A length of the first side may be greater than a length of the second side.

The plate lines PL may include various conductive materials such as a doped semiconductor material, a conductive metal, a conductive metal nitride, or a metal oxide. For example, the plate lines PL may include a doped semiconductor material, a conductive metal nitride (e.g., titanium nitride, tantalum nitride, niobium nitride, or tungsten nitride), a metal (e.g., ruthenium, iridium, titanium, or tantalum.), and/or a conductive metal oxide (e.g., iridium oxide or niobium oxide), but implementations are not limited thereto. In some implementations, the plate lines PL may be formed of polysilicon and/or copper.

A plurality of first trenches TCH1 may be provided in the capacitor structure 100. The first trenches TCH1 may penetrate through the plate lines PL that form a single column. A plurality of first trenches TCH1 may be provided within the plate lines PL that form a single column. For example, four first trenches TCH1 may be provided within the plate lines PL that form a single column, as illustrated in the drawings.

First insulating layers 110 may be provided between the transistor structure 10 and the lowermost plate line PL, and between two adjacent rows of plate lines PL. First insulating layers 110 may not be provided between two adjacent columns of plate lines PL.

The first insulating layers 110 and the plate lines PL may be alternately arranged in the third direction D3.

Each of the first insulating layers 110 may include an insulating material, for example, at least one of a silicon oxide, a silicon nitride, and a silicon oxynitride, but are not limited thereto. For example, the first insulating layer 110 may include a silicon oxide.

Ferroelectric layers 131 may be provided on inner side surfaces of the first trenches TCH1. The ferroelectric layers 131 may cover side surfaces of the first trenches TCH1. The ferroelectric layer 131 may be conformally arranged on sidewalls of the plurality of first trenches TCH1. The ferroelectric layer 131 may not be provided on a bottom surface of the plurality of first trenches TCH1. The ferroelectric layer 131 may be alternately in contact with the plate lines PL and the first insulating layers 110 in the extending direction of the first trenches TCH1. For example, a portion of the ferroelectric layer 131 may be in contact with the plate lines PL, and another portion of the ferroelectric layer 131 may be in contact with the first insulating layer 110.

In some implementations, the ferroelectric layer 131 may include a ferroelectric layer, a ferroelectric layer, an antiferroelectric layer, and/or combinations thereof. For example, when the ferroelectric capacitor has non-volatile memory characteristics, the ferroelectric layer 131 may include one of a ferroelectric layer, a combination of a ferroelectric layer and an antiferroelectric layer, and a combination of a ferroelectric layer and a ferroelectric layer. For example, when the ferroelectric capacitor has volatile memory characteristics, the ferroelectric layer 131 may include one of a ferroelectric layer, a combination of a ferroelectric layer and an antiferroelectric layer, and a combination of a ferroelectric layer and a ferroelectric layer. However, the present disclosure is not limited thereto.

In some implementations, the ferroelectric material may include one of lead zirconate titanate (PZT), strontium bismuth tantalate (SBT), or bismuth lanthanum titanate (BLT). In addition, the ferroelectric capacitor may include, for example, at least one of hafnium oxide, hafnium zirconium oxide, zirconium oxide, barium strontium titanium oxide, barium titanium oxide, and lead zirconium titanium oxide. The hafnium zirconium oxide may be a material in which zirconium (Zr) is doped into hafnium oxide, or may be a compound of hafnium (Hf), zirconium (Zr), and oxygen (O). Each ferroelectric material may further include a doping element doped into the materials described above. The doping element may be an element selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn).

In some implementations, the ferroelectric layer may include, for example, a perovskite-based material, and/or a fluorite-based material.

The ferroelectric layer may include a high-dielectric constant material such as beryllium oxide (BeO₂), magnesium oxide (MaO₂), calcium oxide (CaO₂), strontium oxide (SrO₂), aluminum oxide (Al₂O₃), yttrium oxide (Y₂O₃), scandium oxide (Sc₂O₃), lanthanum oxide (La₂O₃), hafnium oxide (HfO₂), zirconium oxide (ZrO₂), titanium oxide (TiO₂), tantalum oxide (Ta₂O₅), niobium oxide (Nb₂O₅), vanadium oxide (V₂O₅), strontium-titanium oxide (SrTiO₃), or barium-strontium-titanium oxide (BaSrTiO₃). However, the present disclosure is not limited thereto.

The capacitor electrodes 133 may fill the remaining portions within the first trenches TCH1 in which the ferroelectric layers 131 are arranged. The capacitor electrodes 133 may extend in the third direction D3 in which the first trenches TCH1 are formed. At least one capacitor electrode 133 may be provided for each plate line PL. In the present implementation, the capacitor electrode 133 is provided for each first trench TCH1 of each plate line PL and is illustrated as including four capacitor electrodes. However, the number of capacitor electrodes 133 is not limited thereto and may be different.

Each of the capacitor electrodes 133 may include, for example, a doped semiconductor material, a conductive metal nitride (e.g., titanium nitride, tantalum nitride, niobium nitride, or tungsten nitride), a metal (e.g., ruthenium, iridium, titanium, or tantalum), and a conductive metal oxide (e.g., iridium oxide or niobium oxide), but implementations are not limited thereto.

Among the capacitor electrodes 133, the plate lines PL, and the ferroelectric layers 131, a single capacitor electrode 133 and a single plate line PL disposed on opposite sides with a single ferroelectric layer 131 interposed therebetween may form a single ferroelectric capacitor.

Plate line select transistors PT may be provided on one side of the ferroelectric capacitors.

The plate line select transistors PT may include plate lines PL, global plate lines GPL, selection semiconductor patterns 141, selection gate insulating layers 143, and selection gate electrodes 145.

A plurality of second trenches TCH2 may be provided in the capacitor structure 100. The second trenches TCH2 may penetrate through both the plate lines PL forming a single column and the global plate lines GPL provided in the same layer as the plate lines PL forming a single column. A single second trench TCH2 may be provided for the plate lines PL forming a single column.

The global plate lines GPL may be spaced apart from the plate lines PL with the second trenches TCH2 interposed therebetween. The global plate lines GPL may be stacked in the third direction D3. The global plate lines GPL may be provided in the same number as the number of rows of the plate lines PL to correspond to the rows of the plate lines PL. In some implementations, each of the global plate lines GPL may be provided in the same layer as the plate lines PL of the same row. The global plate lines GPL provided on a single layer may be connected to each other. For example, a single global plate line GPL may be provided on a single layer.

The global plate lines GPL may include substantially the same material as the plate lines PL.

The selection gate electrodes 145 may be arranged within the second trenches TCH2. The selection gate electrodes 145 may extend in the third direction D3 within the second trenches TCH2. In some implementations, each of the selection gate electrodes 145 may be connected to a corresponding one of the wordlines WL of the transistor structure 10.

Each of the selection gate electrodes 145 may include, for example, a doped semiconductor material, a conductive metal nitride (e.g., titanium nitride, tantalum nitride, niobium nitride, or tungsten nitride), a metal (e.g., ruthenium, iridium, titanium, or tantalum), and a conductive metal oxide (e.g., iridium oxide or niobium oxide), but implementations are not limited thereto.

Selection semiconductor patterns 141 may surround an outer side surface of each selection gate electrode 145. The selection semiconductor patterns 141 may be provided in the same number as the number of rows of the plate lines PL to correspond to the rows of the plate lines PL. The selection semiconductor patterns 141 may be provided on the same plane as each of the plate lines PL. In some implementations, each of the selection semiconductor patterns 141 may be provided in the same layer as the plate lines PL of the same row.

In plan view, each selection semiconductor pattern 141 may be provided in a ring shape and may be provided between the corresponding selection gate electrode 145 and the plate line PL adjacent to the selection gate electrode 145. The selection semiconductor patterns 141 may also be provided between the corresponding selection gate electrode 145 and the global plate line GPL adjacent to the selection gate electrode 145. One side of the selection semiconductor patterns 141 may be connected to the plate line PL adjacent to the selection gate electrode 145, and another side of the selection semiconductor patterns 141 may be connected to the global plate line GPL adjacent to the selection gate electrode 145. The plate lines PL and the global plate lines GPL, opposing each other with the selection semiconductor patterns 141 interposed therebetween, may be spaced apart from each other. A selection gate insulating layer 143 may be provided between the selection gate electrode 145 and the selection semiconductor patterns 141. The selection gate insulating layer 143 may conformally cover the selection gate electrode 145.

The global plate line GPL and the plate line PL, opposing each other with a single selection semiconductor pattern 141 interposed therebetween, may function as a source electrode and a drain electrode, respectively. A single gate electrode, a selection semiconductor pattern 141 surrounding the single gate electrode, and a global plate line GPL and a plate line PL disposed to oppose each other with the selection semiconductor pattern 141 interposed therebetween may form a single plate line select transistor PT.

The capacitor structure 100 may include an upper insulating layer 150. The upper insulating layer 150 may cover the first insulating layers 110, the plate lines PL, the global plate lines GPL, the capacitor electrodes 133, the selection gate electrodes 145, or the like. The upper insulating layer 150 may include an oxide-based insulating material. The upper insulating layer 150 may include, for example, at least one of silicon oxide, silicon oxynitride, and a low-K material having a lower dielectric constant than silicon oxide, but implementations are not limited thereto.

In the capacitor structure 100, the staircase region SPT may include a portion of the global plate lines GPL, a portion of the first insulating layers 110, and plate line contact plugs CP.

The staircase region SPT may be provided on one side of the capacitor region CPT. The staircase region SPT and the capacitor region CPT may be sequentially arranged in the second direction D2.

The global plate lines GPL may extend from the capacitor region CPT to the staircase region SPT. In plan view, the global plate lines GPL in the staircase region SPT may extend in a predetermined direction. For example, in the staircase region SPT, the global plate lines GPL may extend in the second direction D2. In plan view, the extending direction of the global plate lines GPL may be perpendicular to the extending direction of each plate line PL. Accordingly, when viewed from the first to third directions D3, the global plate lines GPL may not overlap the plate lines PL.

The global plate lines GPL in the staircase region SPT may have different lengths in the second direction D2. The global plate lines GPL may decrease in length in the second direction D2 in a direction from a lowermost layer to an uppermost layer. For example, if the global plate lines PL arranged from the bottom to the top are referred to as first to fourth global plate lines GPL<0>, GPL<1>, GPL<2>, and GPL<3>, then the first to fourth global plate lines GPL<0>, GPL<1>, GPL<2>, and GPL<3> may sequentially decrease in lengths in the second direction D2. However, the direction of the staircases in the staircase region SPT is not limited thereto. For example, the global plate lines GPL may decrease in length in the second direction D2 from the uppermost layer to the lowermost layer. The first to fourth global plate lines GPL<0>, GPL<1>, GPL<2>, and GPL<3> may sequentially have longer lengths. As described above, the global plate lines GPL in the staircase region SPT may be stacked in a staircase shape.

The first insulating layers 110 between the first device part 10 and the first global plate line GPL<0> and between the second to fourth adjacent global plate lines GPL<1>, GPL<2>, and GPL<3> may also have shorter lengths in the second direction D2 from the lowermost layer to the uppermost layer. In the staircase region SPT, an end side surface of each global plate line GPL and an end side surface of a corresponding first insulating layer 110 may be substantially coplanar.

A portion of the upper surface of each of the global plate lines GPL may not be covered by the first insulating layer 110 disposed directly thereabove.

The upper insulating layer 150 may be provided on the global plate lines GPL of the staircase region SPT.

Trenches may be provided in the upper insulating layer 150 to expose a portion of upper surfaces of the global plate lines GPL that are not covered by the first insulating layer 110. The trenches may be provided to correspond to each of the global plate lines GPL. Plate line contact plugs CP may be provided within the trenches. For example, first to fourth plate line contact plugs CP0, CP1, CP2, and CP3 (hereinafter, “CP”) connected to the first to fourth global plate lines GPL<0>, GPL<1>, GPL<2>, and GPL<3> may be provided in each of the trenches, respectively. The plate line contact plugs CP may be sequentially arranged in the extending direction of the global plate lines GPL, for example, the second direction D2. In some implementations, the first to fourth plate line contact plugs CP0, CP1, CP2, and CP3 may be provided with different lengths, and may all have upper surfaces arranged on the same plane. However, the present disclosure is not limited thereto. In some implementations, when the global plate lines GPL increase in lengths in a direction from the uppermost layer to the lowermost layer, trenches may be provided to expose a portion of the lower surfaces of the global plate lines GPL, and plate line contact plugs CP may be provided in the trenches.

The plate line contact plugs CP may include a conductive material. For example, the plate line contact plugs CP may include tungsten (W) or copper (Cu), but implementations are not limited thereto.

The plate line contact plugs CP may apply a voltage to each of the corresponding global plate lines GPL.

In some implementations, the semiconductor device may further include a peripheral circuit structure in addition to the transistor structure 10. The peripheral circuit structure may include a peripheral circuit substrate and peripheral circuit elements.

The peripheral circuit structure may be provided below the transistor structure 10, but is not limited thereto, and may be provided on the capacitor structure 100. At least a portion of the peripheral circuit structure may vertically overlap the capacitor structure 100 and/or the transistor structure 10. The peripheral circuit structure may also be provided on an additional substrate to be electrically connected to the transistor structure 10 and/or the capacitor structure 100.

The peripheral circuit substrate may include a semiconductor substrate such as a silicon substrate, a germanium substrate, or a silicon-germanium substrate. Alternatively, the peripheral circuit substrate may include a silicon-on-insulator (SOI) substrate, a germanium-on-insulator (GOI) substrate, or the like.

Peripheral circuit elements may be formed on the peripheral circuit substrate. The peripheral circuit elements may constitute a peripheral circuit that controls the operation of each memory cell of the semiconductor device. For example, the peripheral circuit elements may include a control logic, a row decoder, a page buffer, or the like. The peripheral circuit elements may include, for example, transistors, but implementations are not limited thereto. For example, the peripheral circuit elements may include various passive elements such as capacitors, resistors, and inductors, as well as various active elements such as transistors.

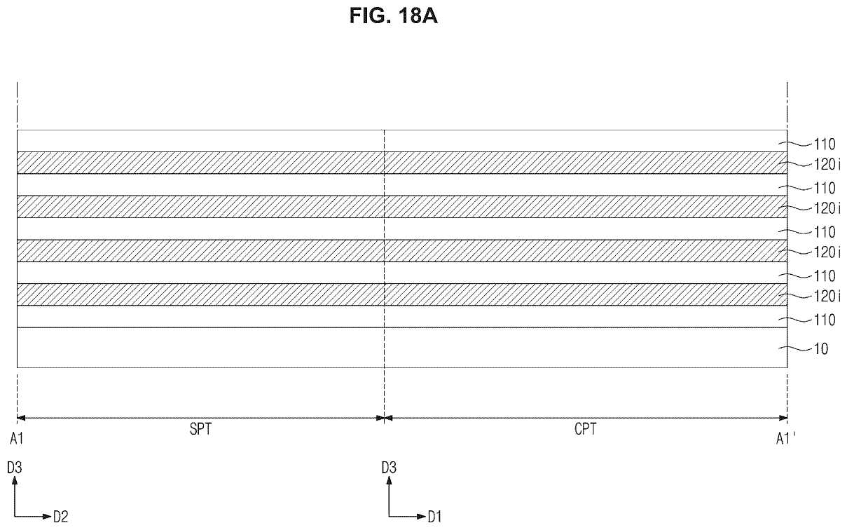

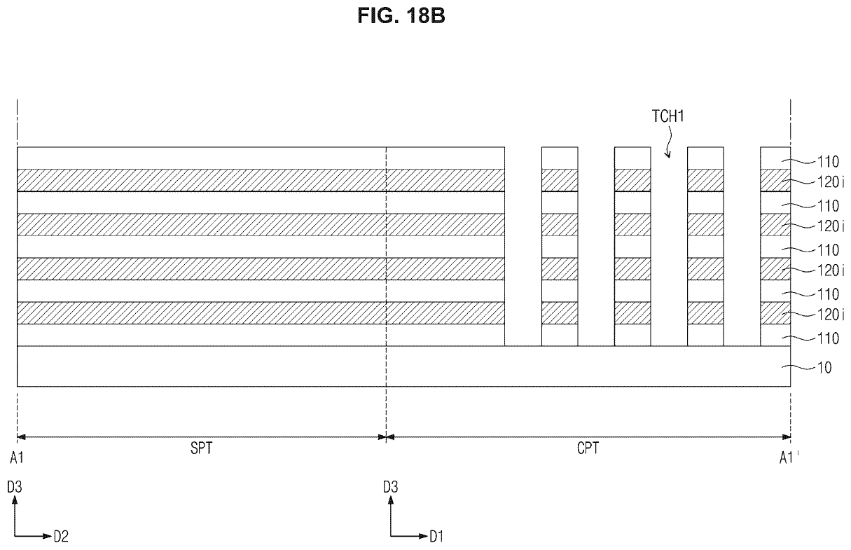

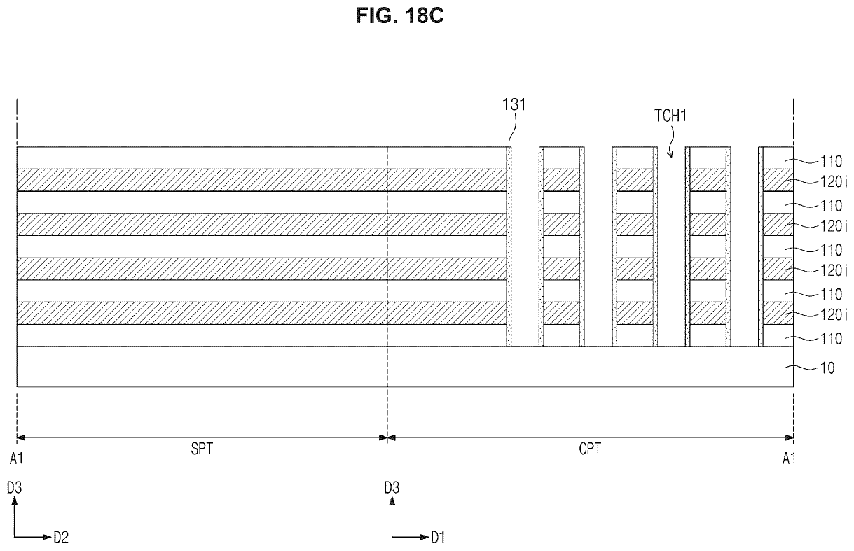

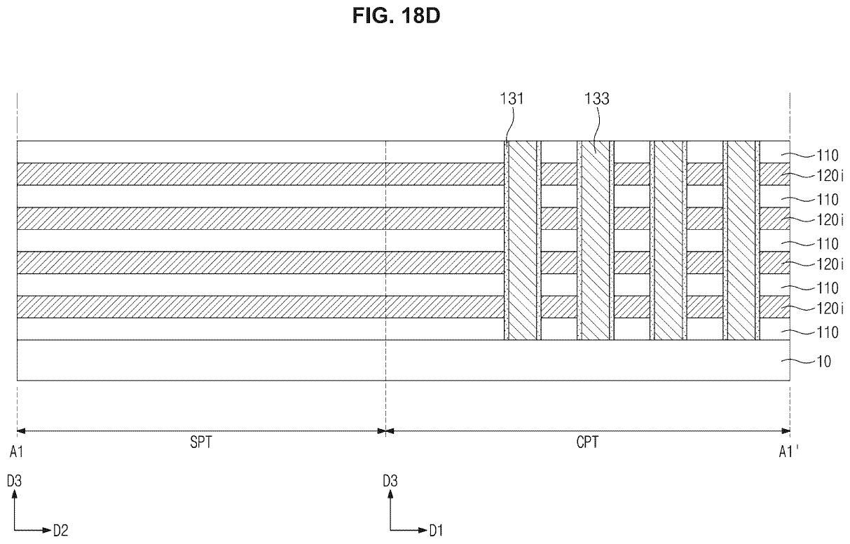

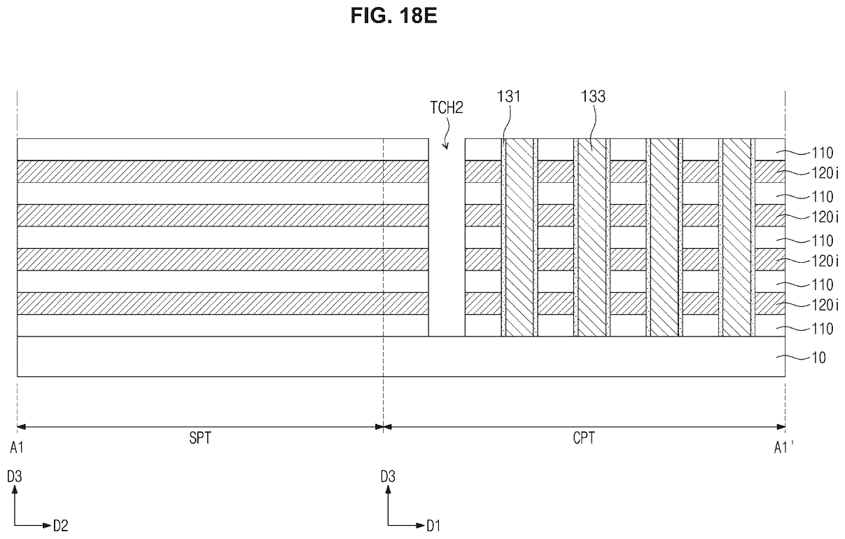

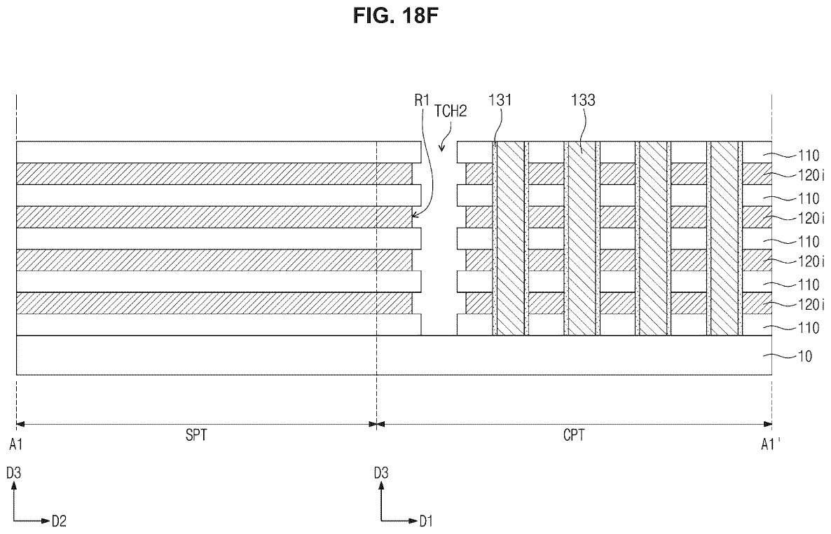

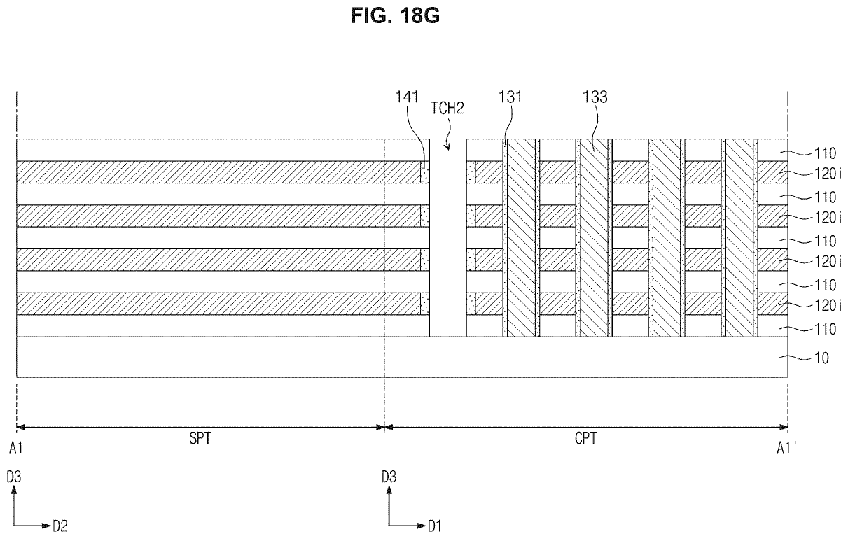

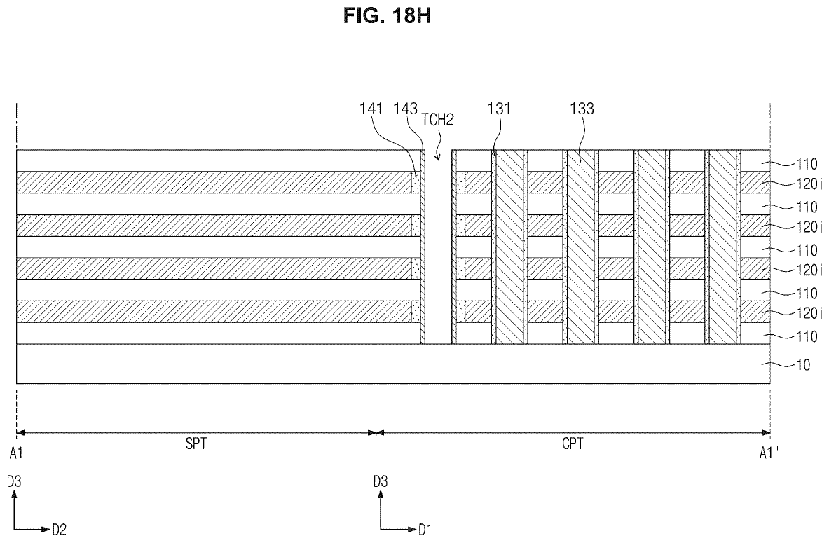

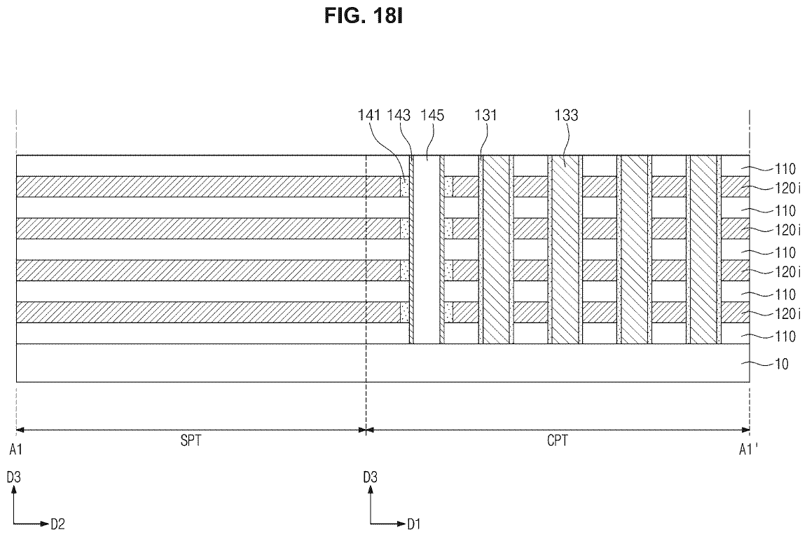

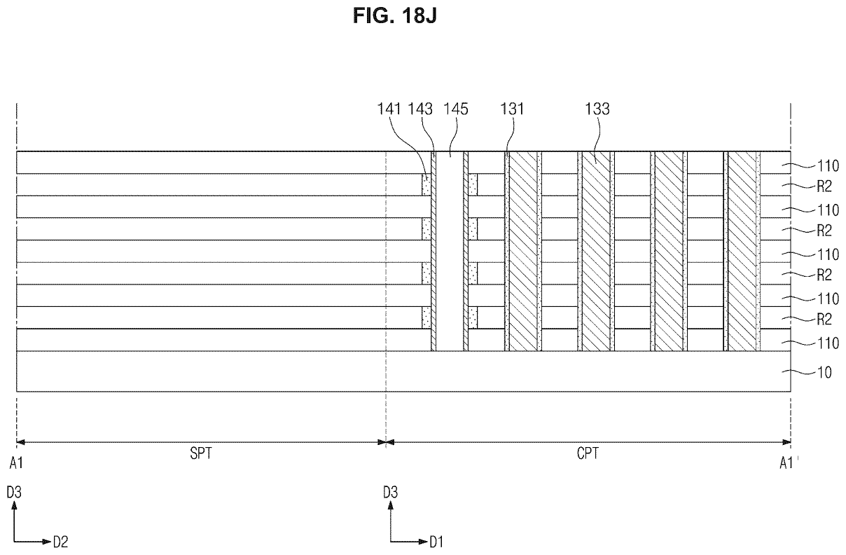

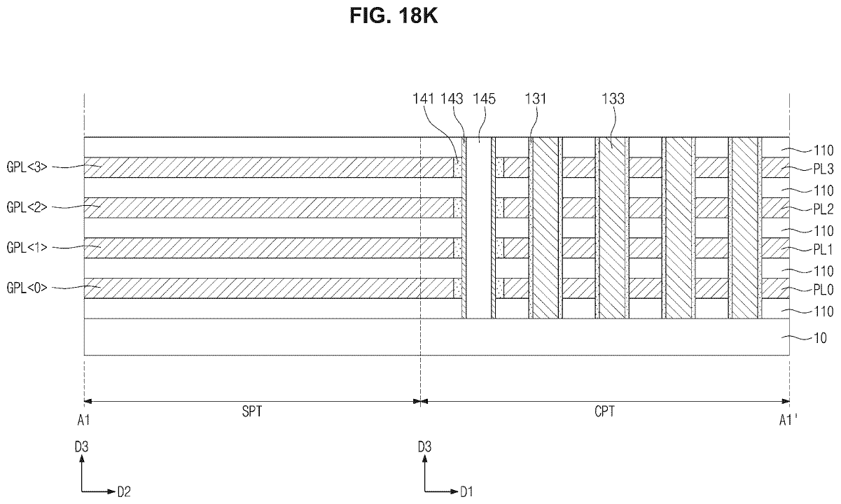

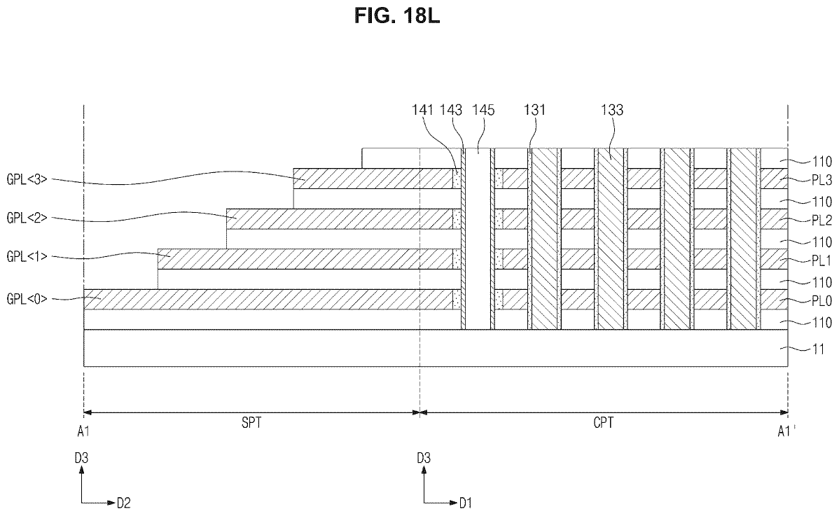

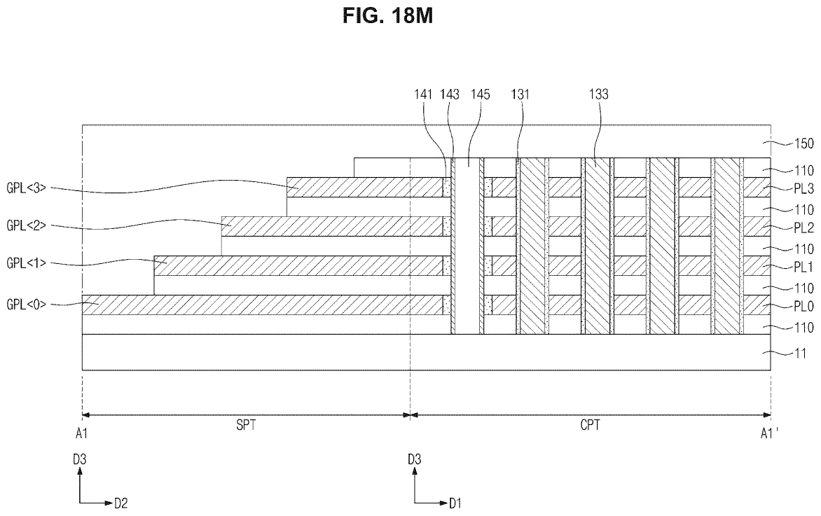

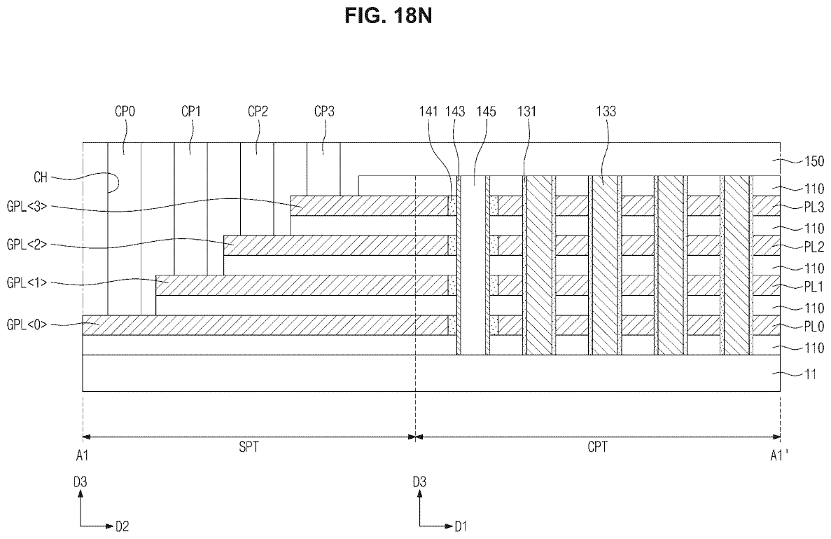

FIGS. 18A to 18N are cross-sectional views, sequentially illustrating a method of manufacturing the semiconductor device illustrated in FIG. 16 and are cross-sectional views corresponding to FIG. 17A.

Referring to FIG. 18A, first insulating layers 110 and sacrificial layers 120i may be alternately stacked on a transistor structure 10.

In the present implementation, a substrate 11 is illustrated as a base material on which the first insulating layers 110 and the sacrificial layers 120i are stacked, but implementations are not limited thereto. For example, the substrate 11 can be replaced by others as long as they are for manufacturing a semiconductor device. In this case, the substrate 11 may be, for example, a wafer. The wafer may include, for example, silicon (Si). The wafer may include a semiconductor element such as germanium (Ge), or a compound semiconductor such as silicon carbide (SiC), gallium arsenide (GaAs), indium arsenide (InAs), or indium phosphide (InP). According to some implementations, the wafer may have an SOI (silicon on insulator) structure. In some implementations, the substrate 11 may include substrates on which a series of processes for manufacturing a semiconductor device are performed or are to be performed. For example, such processes may include an ion doping process, an oxidation process to form an oxide layer, a lithography process including spin coating, exposure, and development, a thin film deposition process including chemical vapor deposition (CVD), atomic layer deposition (ALD), and physical vapor deposition (PVD), a dry etching process, a wet etching process, or a metal wiring process.

The first insulating layers 110 and the sacrificial layers 120i may have an etching selectivity. For example, the first insulating layers 110 may include an oxide-based insulating material, and the sacrificial layers 120i may include a nitride-based insulating material. In some implementations, the sacrificial layers 120i may include doped polysilicon. However, the present disclosure is not limited thereto, and the sacrificial layers 120i may include other materials.

Referring to FIG. 18B, a portion of the first insulating layers 110 and the sacrificial layers 120i may be removed to form a plurality of first trenches TCH1. The plurality of first trenches TCH1 may penetrate through the first insulating layers 110 and the sacrificial layers 120i. In plan view, each of the first trenches TCH1 may have various shapes. For example, each of the first trenches TCH1 may be circular, elliptical, or rectangular, and may have other shapes.

In some implementations, side surfaces of the first insulating layers 110 and the sacrificial layers 120i forming the first trenches TCH1 may be coplanar. However, implementations are not limited thereto, and one side surface of either one of the first insulating layers 110 or the sacrificial layers 120i may be partially recessed in a horizontal direction.

Referring to FIG. 18C, ferroelectric layers 131 may be formed along the side surfaces of the first trenches TCH1. The ferroelectric layers 131 may be formed along the side surfaces of the first insulating layers 110 and the sides of the sacrificial layers 120i. The ferroelectric layers 131 may conformally cover the sidewalls of each first trench TCH1, but implementations are not limited thereto.

The ferroelectric layers 131 may not be formed on the bottom surfaces of the first trenches TCH1, but implementations are not limited thereto. In other implementations, the ferroelectric layer 131 may also be formed on bottom surfaces of the first trenches TCH1. When the ferroelectric layer 131 is also formed on the bottom surfaces of the first trenches TCH1, an additional process may then be performed to remove the ferroelectric layer 131 formed on the bottom surface.

Each of the ferroelectric layers 131 may be formed by an appropriate process such as atomic layer deposition (ALD), chemical vapor deposition (CVD), molecular beam deposition (MBD), or physical vapor deposition (PVD) using a ferroelectric material as a material. The ferroelectric material may include one of lead zirconate titanate (PZT), strontium bismuth tantalate (SBT), or bismuth lanthanum titanate (BLT). A ferroelectric capacitor (FCk) may include, for example, at least one of hafnium oxide, hafnium zirconium oxide, zirconium oxide, barium strontium titanium oxide, barium titanium oxide, and lead zirconium titanium oxide. The hafnium zirconium oxide may be a material in which zirconium (Zr) is doped into hafnium oxide, or may be a compound of hafnium (Hf), zirconium (Zr), and oxygen (O). Each of the ferroelectric capacitors 22-1 to 22-i may further include a doping element doped into the above-mentioned material. The doping element may be an element selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn).

Referring to FIG. 18D, capacitor electrodes 133 may be formed within the first trenches TCH1 where the ferroelectric layers 131 are formed. The capacitor electrodes 133 may fill the first trenches TCH1 surrounded by the ferroelectric layers 131.

Referring to FIG. 18E, a portion of the first insulating layers 110 and the sacrificial layers 120i may be removed to form second trenches TCH2. The second trenches TCH2 may penetrate through the second insulating layers 30 and the sacrificial layers 120i. In some implementations, the second trenches TCH2 may be formed deeper than the first trenches TCH1. Forming the second trenches TCH2 deeper than the first trenches TCH1 enables the selection gate electrodes 145 to be formed in the second trenches TCH2 to be connected to the wordlines WL in a subsequent operation of forming the first device part 10. This will be described later.

In plan view, each of the second trenches TCH2 may have various shapes. For example, each of the second trenches TCH2 may be circular, elliptical, or rectangular, and may have other shapes.

Referring to FIG. 18F, a portion of the sacrificial layers 120i may be removed to form first recesses R1. The first recesses R1 may be formed by isotropically etching a portion of the sacrificial layer 120i exposed to the outside by the second trenches TCH2. A portion of the sacrificial layers 120i may be removed through a wet etching process. The sacrificial layers 120i and the first insulating layers 110 have an etching selectivity, so that the first recesses R1 may be formed by selectively removing a portion of the sacrificial layers 120i. The first insulating layers 110 may not be removed during the removal of a portion of the sacrificial layers 120i.

Referring to FIG. 18G, selection semiconductor patterns 141 may be formed within the first recesses R1. The side surfaces of the selection semiconductor patterns 141 are illustrated as being disposed on the same plane as the side surfaces of the first insulating layers 110, but the present disclosure is not limited thereto.

Referring to FIG. 18H, selection gate insulating layers 143 may be formed within the second trenches TCH2 in which the selection semiconductor patterns 141 are formed. The selection gate insulating layers 143 may conformally cover the side surfaces of the first insulating layers 110 and the selection semiconductor patterns 141.

Referring to FIG. 18I, selection gate electrodes 145 may be formed within the second trenches TCH2 where the selection gate insulating layers 143 are formed. The selection gate electrodes 145 may fill the remaining portions within the second trenches TCH2.

Referring to FIG. 18J, the sacrificial layers 120i may be selectively removed to form second recesses R2. The second recesses R2 may be formed by selectively etching only the sacrificial layers 120i while leaving the first insulating layers 110 using an etching selectivity between the first insulating layers 110 and the sacrificial layers 120i.

In some implementations, at least one etching trench penetrating through the first insulating layers 110 and the sacrificial layers 120i, may be additionally formed to efficiently etch the sacrificial layers 120i. The sacrificial layers 120i may be removed between the etching trenches.

Referring to FIG. 18K, plate lines PL and global plate lines GPL may be formed within the second recesses R2. For example, first to fourth plate lines PL1, PL2, PL3, and PL4 and first to fourth global plate lines GPL<0>, GPL<1>, GPL<2>, and GPL<3> may be formed within the second recesses R2. The first to fourth plate lines PL1, PL2, PL3, and PL4 and the first to fourth global plate lines GPL<0>, GPL<1>, GPL<2>, and GPL<3> may be formed by filling the second recesses R2.

Accordingly, ferroelectric capacitors composed of plate lines PL, ferroelectric layers 131, and capacitor electrodes 133 may be formed. In addition, plate line select transistors PT including the plate lines PL, the global plate lines GPL, the selection semiconductor patterns 141, and the selection gate electrodes 145 may be formed.

Referring to FIG. 18L, a portion of the first insulating layers 110 and the global plate lines GPL may be removed. In the staircase region SPT, the first insulating layers 110 and the global plate lines GPL may be removed to different extents. For example, a portion of the second global plate line GPL and an underlying first insulating layer 110 may be removed to have a shorter length in the second direction D2 than the first global plate line GPL and an underlying first insulating layer 110. Similarly, a portion of the second global plate line GPL and an underlying first insulating layer 110 may be removed to have a shorter length in the second direction D2 than the third global plate line GPL and an underlying first insulating layer 110. A staircase shape may be formed by sequentially removing a portion of the global plate lines GPL and the first insulating layers 110 in the same manner.

In some implementations, in the capacitor region CPT, a portion of the first insulating layers 110 and the plate lines PL may be removed to form a plurality of columns of plate lines PL.

Referring to FIG. 18M, an upper insulating layer 150 may be formed on the plate line select transistors and ferroelectric capacitors including the plate lines PL and the global plate lines GPL. The upper insulating layer 150 may cover all upper surfaces of the global plates GPL arranged in a staircase shape.

Referring to FIG. 18N, plate line contact plugs CP can be formed within the upper insulating layer 150. The plate line contact plugs CP may be formed by a process of removing a portion of the upper insulating film 150 to form contact holes exposing a portion of the top surfaces of the global plates GPL arranged in a staircase shape, and then filling the contact holes.

The capacitor structure 100 may be manufactured through the above-described process.

In some implementations, the capacitor structure 100 may be modified in various ways without departing from the present disclosure. For example, in the staircase region SPT, the global plate lines GPL may extend in various directions. The plate line contact plugs CP may be arranged to correspond to the global plate lines GPL in the extending direction of the global plate lines GPL.

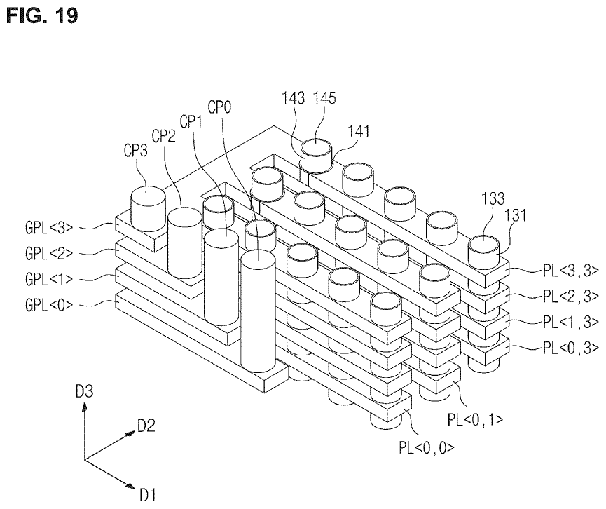

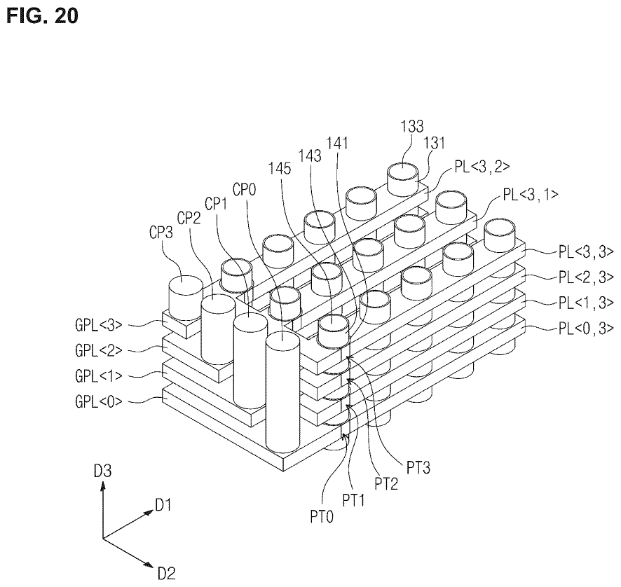

FIGS. 19 and 20 are perspective views illustrating a semiconductor device according to some implementations.

Referring to FIG. 19, a staircase region SPT and a capacitor region CPT may be sequentially arranged in a second direction D2. The global plate lines GPL may extend from the capacitor region CPT to the staircase region SPT.

In the above-described implementation, the global plate lines GPL extended in the second direction D2. However, in the present implementation, the global plate lines GPL may extend in a different direction. For example, in the present implementation, the global plate lines GPL may extend in a first direction D1. Accordingly, each global plate line GPL may be parallel to the extending direction of each plate line PL. The global plate lines GPL may be spaced apart from adjacent plate lines PL with an upper insulating layer 150 interposed therebetween.

The global plate lines GPL in the staircase region SPT may have different lengths in the first direction D1. The global plate lines GPL may have a shorter length in a direction from a lowermost layer to an uppermost layer. For example, the first to fourth global plate lines GPL may sequentially have shorter lengths.

Referring to FIG. 20, a staircase region SPT and a capacitor region CPT may be sequentially arranged in a first direction D1. Accordingly, when viewed from the first direction D1, the staircase region SPT and the capacitor region CPT may overlap each other.

The global plate lines GPL may extend from the capacitor region CPT to the staircase region SPT and may extend in a second direction D2. Accordingly, each of the global plate lines GPL may be perpendicular to the extending direction of each plate line PL. The global plate lines GPL may be spaced apart from adjacent plate lines PL with an upper insulating layer 150 interposed therebetween.

The global plate lines GPL in the staircase region SPT may have different lengths in the second direction D2. The global plate lines GPL may have a shorter length in a direction from a lowermost layer to an uppermost layer. For example, the first to fourth global plate lines GPL may sequentially have shorter lengths.

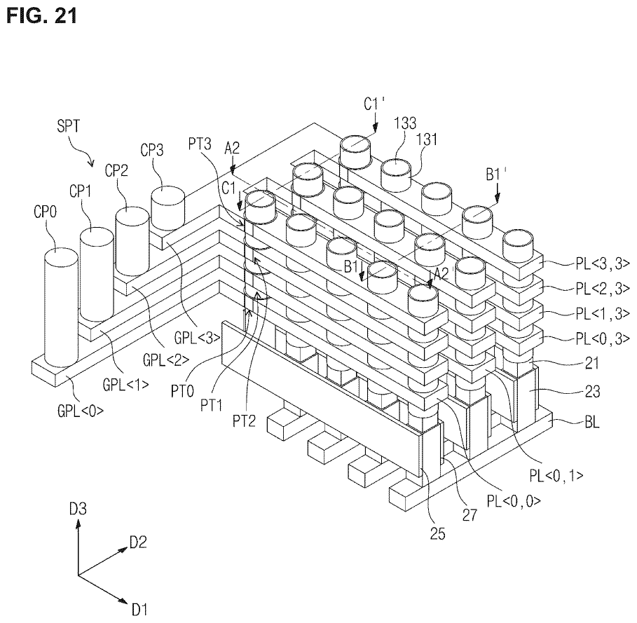

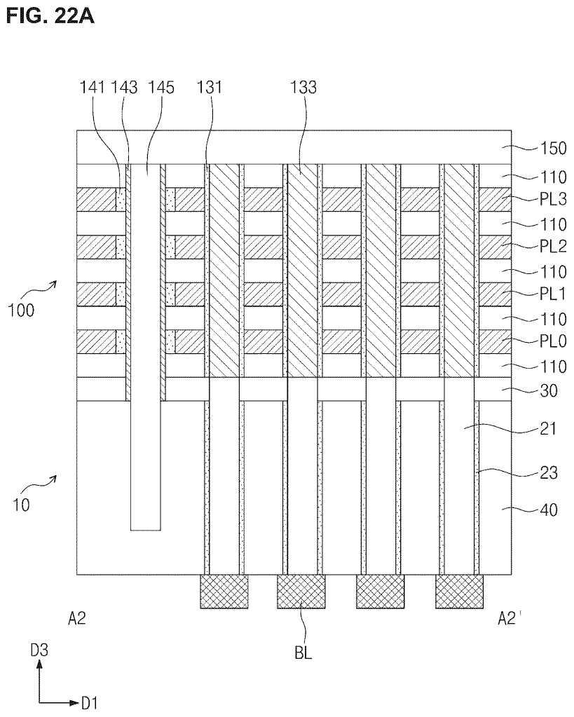

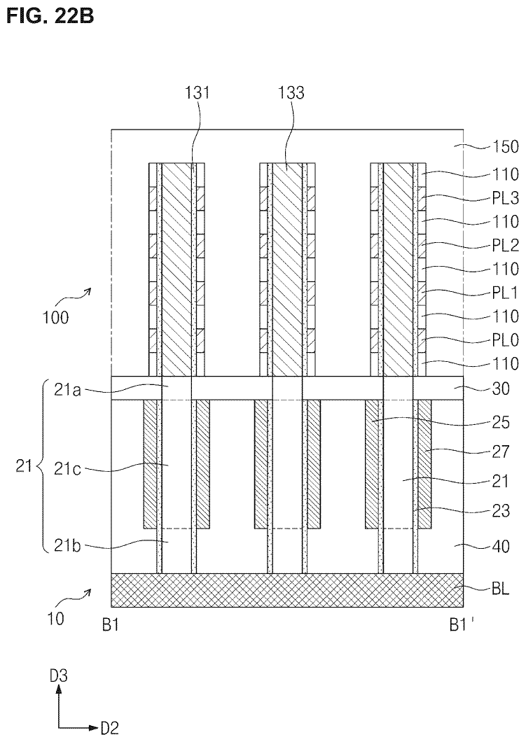

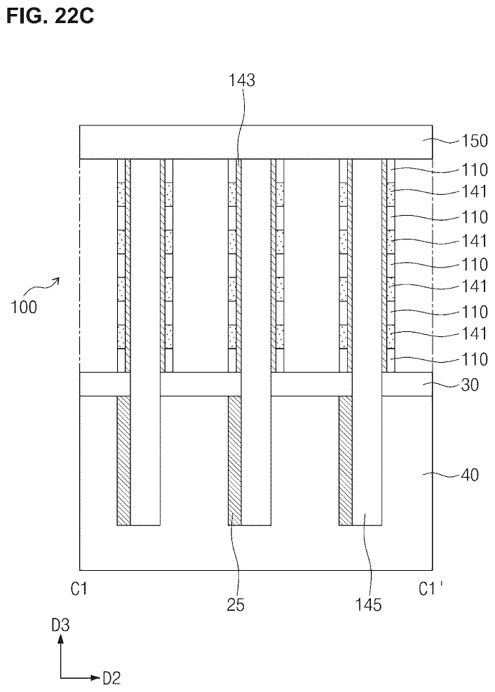

FIG. 21 is a perspective view illustrating a semiconductor device corresponding to the circuit diagram of FIG. 15, and illustrates a case in which the semiconductor device includes both a capacitor structure 100 and a transistor structure 10. FIGS. 22A, 22B, and 22C are cross-sectional views taken along lines A2-A2′, B1-B1′, and C1-C1′ of FIG. 16.

Referring to FIGS. 15, 21, and 22A to 22C, a capacitor structure 100 may be provided on a transistor structure 10. The transistor structure 10 may correspond to the first device part 10 and may include first gate electrodes 25 corresponding to wordlines WL, bitlines BL, semiconductor patterns 21, second gate electrodes 27, and selection gate insulating layers 143. The semiconductor patterns 21, the first gate electrodes 25, the second gate electrodes 27, and the selection gate insulating layers 143 may form access transistors.

The access transistors may be vertical channel transistors. The vertical channel transistor may have a structure in which a channel region 21c extends in a vertical direction, that is, a third direction D3. However, the type of access transistors is not limited thereto and the access transistors may be provided in various forms. For example, the access transistors may include at least one of a buried channel access transistor (BCAT), a planar transistor, a fin-type transistor (FinFET), and/or a multi-bridge channel transistor (MBCFET).

The semiconductor patterns 21 may be vertical semiconductor patterns extending in the third direction D3. In some implementations, each of the semiconductor patterns 21 has a rectangular shape in plan view, but implementations are not limited thereto. For example, each of the semiconductor patterns 21 may have a rounded rectangular shape in plan view.

Each of the semiconductor patterns 21 may include a first source/drain region 21a, a second source/drain region 21b, and a channel region 21c. The first source/drain region 21a may be provided at an upper end portion of each of the semiconductor patterns 21, and the second source/drain region 21b may be provided at a lower end portion of each of the semiconductor patterns 21. In some implementations, the first source/drain region 21a may be connected to the capacitor electrode 133 of the capacitor structure 100, and the second source/drain region 21b may be connected to the bitline BL. In some implementations, additional contact patterns may be further provided between the first source/drain region 21a and the capacitor electrode 133 and/or between the second source/drain region 21b and the bitline.

The first and second source/drain regions 21a and 21b may each function as a source or drain to supply or discharge carriers that carry current. Here, the carrier may be an electron or a hole. The channel region 21c may function as a path through which the carriers move. For example, the first source/drain region 21a may function as a source, the second source/drain region 21b may function as a drain, and the channel region 21c may function as a path for carriers to move between the source and the drain. The first and second source/drain regions 21a and 21b may be regions doped with impurities having a conductivity type, different from that of the channel region 21c. For example, when the channel region 21c includes impurities of a first conductivity type, the first and second source/drain regions 21a and 21b may be regions doped with impurities of a second conductivity type, which is opposite to the first conductivity type. For example, the impurities of the first conductivity type may be p-type impurities such as boron (B), a Group 3 element, and the impurities of the second conductivity type may include n-type impurities such as phosphorus (P) and/or arsenic (As), a Group 5 element.

The semiconductor patterns 21 may include a semiconductor material such as silicon (Si), germanium (Ge), or silicon-germanium (Si—Ge). The vertical semiconductor pattern 21 may include an oxide semiconductor material. The oxide semiconductor material may be, for example, at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and Indium Gallium Zinc Oxide (IGZO). The vertical semiconductor pattern 21 may include a single layer or a multiple layer of oxide semiconductor material. The vertical semiconductor pattern 21 may include amorphous, crystalline, or polycrystalline oxide semiconductor material, but implementations are not limited thereto. In some implementations, the vertical semiconductor pattern 21 may include a single-crystal semiconductor material. Accordingly, the semiconductor patterns 21 may be in a single-crystal state. In some implementations, the vertical semiconductor pattern 21 may have a bandgap energy greater than the bandgap energy of silicon. In some implementations, the vertical semiconductor pattern 21 may include a two-dimensional semiconductor material. The two-dimensional semiconductor material may include, for example, graphene, MoS₂, WS₂, MoSe₂, WSe₂, or combinations thereof.

Gate electrodes may be arranged on opposite sidewalls of the channel region 21c. The gate electrodes may include a first gate electrode 25 provided on one side of the channel region 21c and a second gate electrode 27 arranged on the other side of the channel region 21c. The first gate electrode 25 and the second gate electrode 27 may extend in the first direction D1.

The first gate electrode 25 may function as a wordline and may be referred to as a wordline.

The first gate electrode 25 may be connected to a corresponding one of the plate line select transistors PT. For example, the gate electrode may contact the selection gate electrode 145 of the corresponding plate line select transistor PT. The selection gate electrode 145 may extend in the third direction D3 to be provided inwardly of the transistor structure 10 and may be brought into contact with one of the first gate electrodes 25 extending in the first direction D1 in an intersecting region.

The second gate electrode 27 may be a back gate electrode. The second gate electrode 27 may have a shorter length than the first gate electrode 25 and may not contact the selection gate electrode 145. In some implementations, during operation of the semiconductor device, a negative voltage may be applied to the back gate electrode, which may increase the threshold voltage of the vertical channel transistor. As a result, the back gate electrode may prevent the deterioration of leakage current characteristics caused by the decrease in the threshold voltage as the vertical channel transistor is miniaturized, by controlling the threshold voltage.

A gate insulating layer 23 may be provided between the first gate electrode 25 and the channel region 21c and between the second gate electrode 27 and the channel region 21c to surround the channel region 21c. In some implementations, the gate insulating layer 23 may surround the entire sidewall of the channel region 21c, or may cover a portion of the sidewalls of the first and second gate electrodes 25 and 27. In some implementations, the gate insulating layer 23 may extend in the extending direction of the first and second gate electrodes 25 and 27, for example, in the third direction D3, and may cover only the two sidewalls of the channel region 21c opposing the first and second gate electrodes 25 and 27.

The gate insulating layer 23 may include, for example, a silicon oxide, a silicon nitride, a silicon oxynitride, a high-k material having a higher dielectric constant than silicon oxide, or combinations thereof.

The first gate electrodes 25 and the second gate electrodes 27 may include, for example, a metal, a conductive metal nitride, a conductive metal silicide, a conductive metal oxide, doped polysilicon, or combinations thereof.

The bitlines BL may be connected to each second source/drain region 21b. The bitlines BL extend in the second direction D2 and may be spaced apart from each other at predetermined intervals in the first direction D1.

The bitlines BL may include conductive materials. For example, the bitlines BL may include a metal material (e.g., Al, Cu, Ti, Ta, Ru, W, Mo, Pt, Ni, or Co), a conductive metal nitride (e.g., TiN, TaN, WN, NON, TiAIN, TiSiN, TaSiN, or RuTiN), a conductive metal silicide, a conductive metal oxide (e.g., PtO, RuO₂, IrO₂, SRO(SrRuO₃), BSRO((Ba,Sr)RuO₃), CRO(CaRuO₃), or LSCo), doped polysilicon, or the like.

In some implementations, the bitlines BL are illustrated as being formed as a single layer. However, implementations are not limited thereto and the bitlines BL may also include a semiconductor layer, a barrier pattern, and a low-resistance pattern, which are sequentially stacked. In some implementations, the semiconductor layer may include a polycrystalline semiconductor material, for example, polysilicon, and the low-resistance pattern may include a conductive metal nitride, a metal silicide, or a metal. For example, the low-resistance pattern may include tungsten.

In some implementations, second and third insulating layers 30 and 50 may be arranged between the bitlines BL and a lower surface of the capacitor structure 100.

The second insulating layer 30 may be arranged between the upper insulating layer 150 and upper surfaces of the first and second gate electrodes 25 and 27. The third insulating layer 50 may be provided between the second insulating layer 30 and the bitlines BL. The third insulating layer 50 may be provided between the vertical semiconductor patterns 21. The third insulating layer 50 may electrically isolate the vertical semiconductor patterns 21 from each other. In some implementations, a lower surface of the third insulating layer 50 may be substantially coplanar with bottom surfaces of the semiconductor patterns 21. An upper surface of the third insulating layer 50 may be substantially coplanar with the upper surfaces of the first and second gate electrodes 25 and 27. In some implementations, the second insulating layer 30 and/or the third insulating layer 50 may include a material, different from that of the selection gate insulating layer 143.

In some implementations, the first to third insulating layers 110, 30, and 50 and the upper insulating layer 150 are illustrated as being a single layer. However, implementations are not limited thereto and the first to third insulating layers 110, 30, and 50 and the upper insulating layer 150 may each have a multilayer structure.

The semiconductor device according to some implementations may have the above-described structure, enabling the plate lines PL disposed in the same layer, for example, at the same level, to be connected to one global plate line GPL through a single plate line select transistor PT. The wordline WL may be connected to both the access transistors and the plate line select transistor PT, and a memory cell or a ferroelectric capacitor of a selected row may be selected through a combination of the wordline WL signal and the global plate line GPL signal.

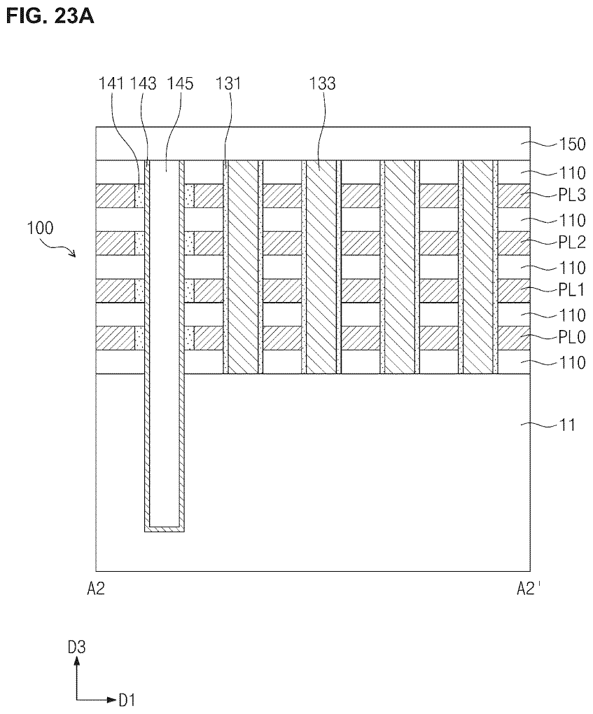

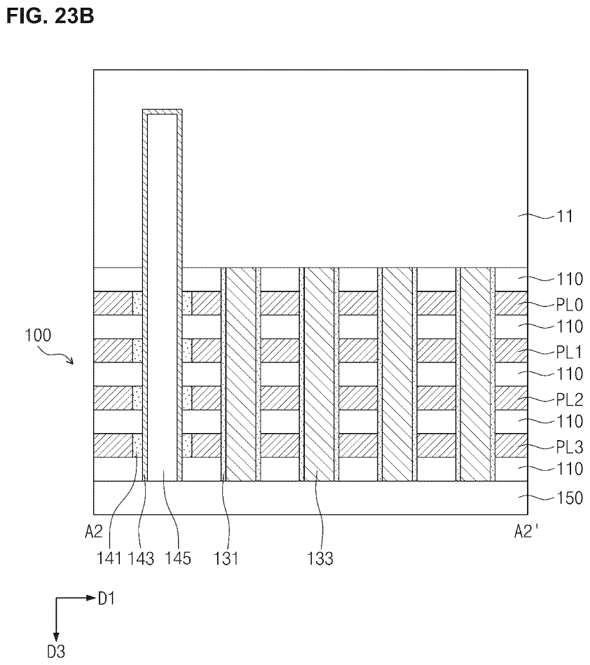

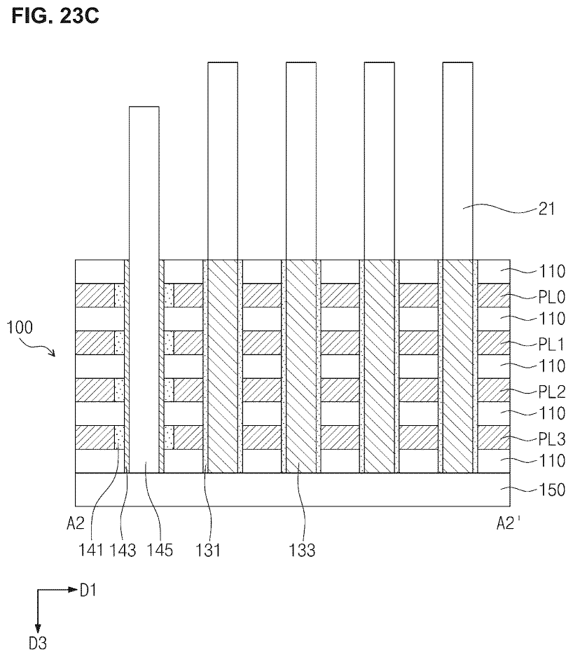

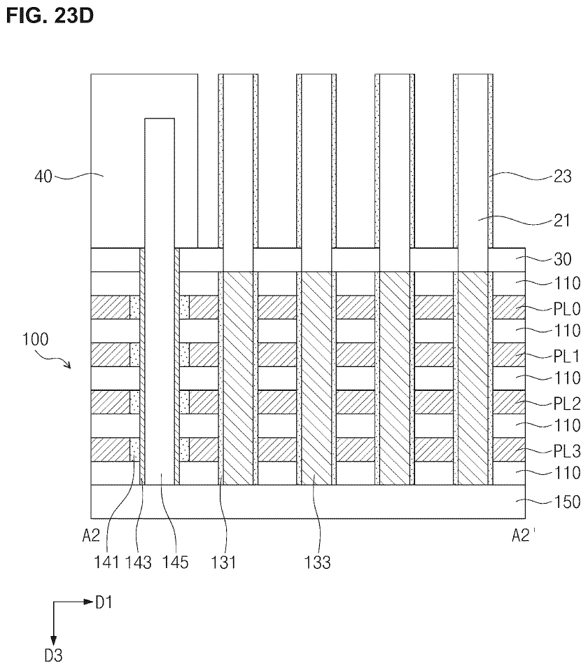

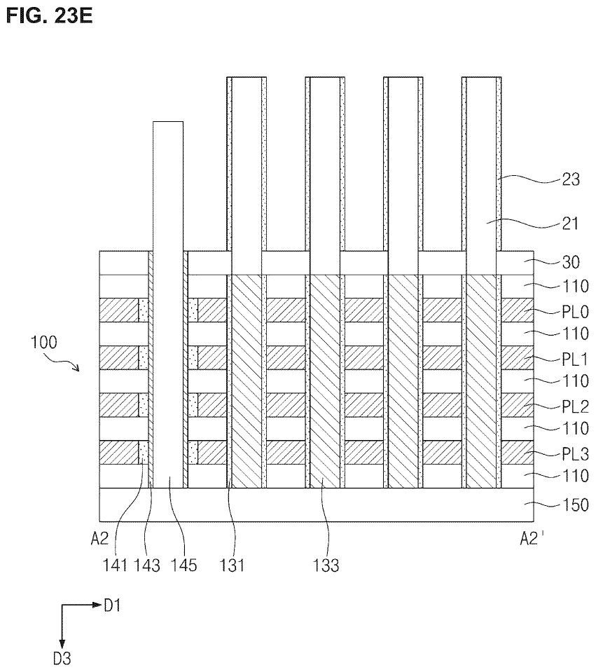

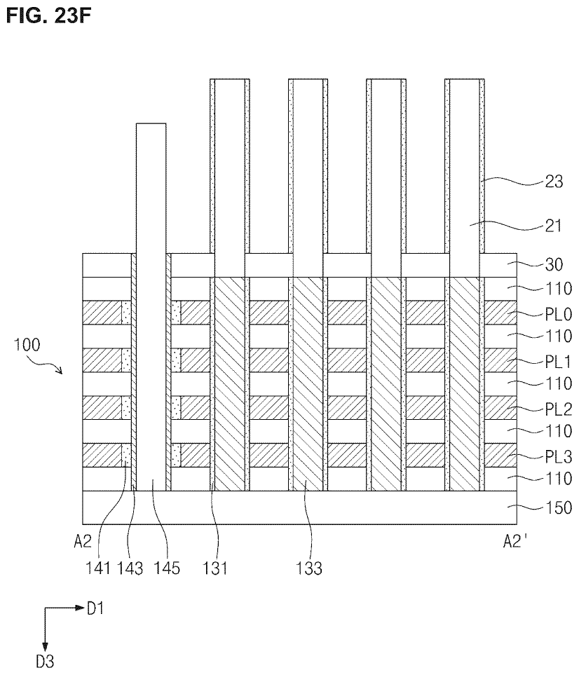

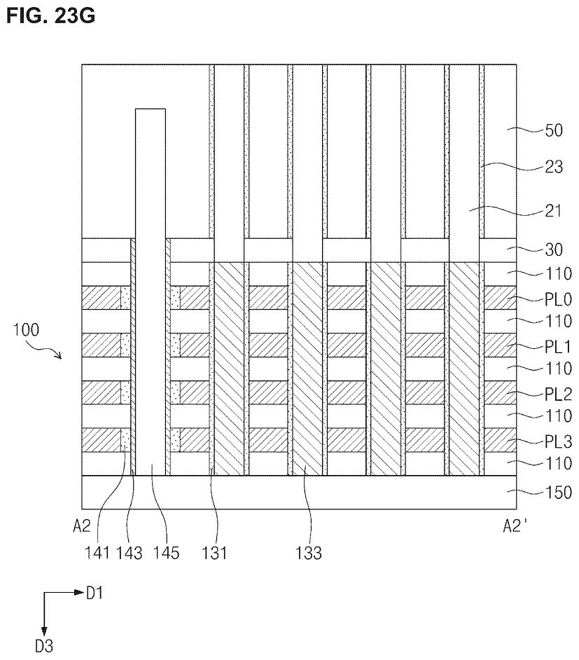

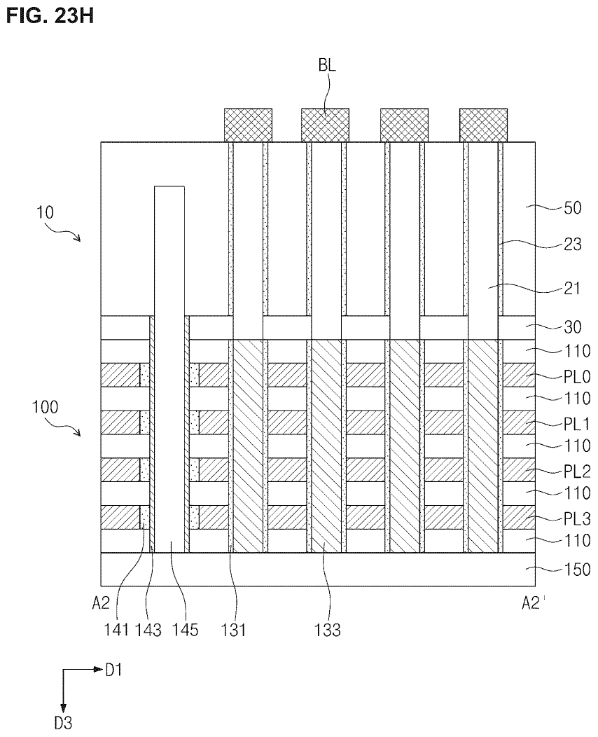

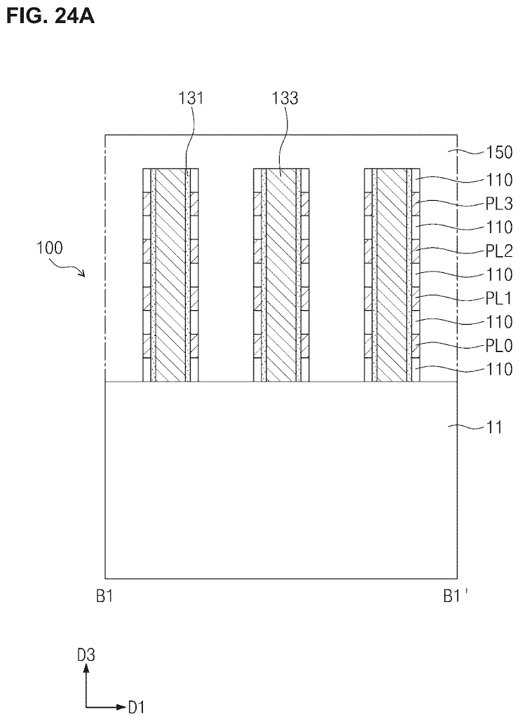

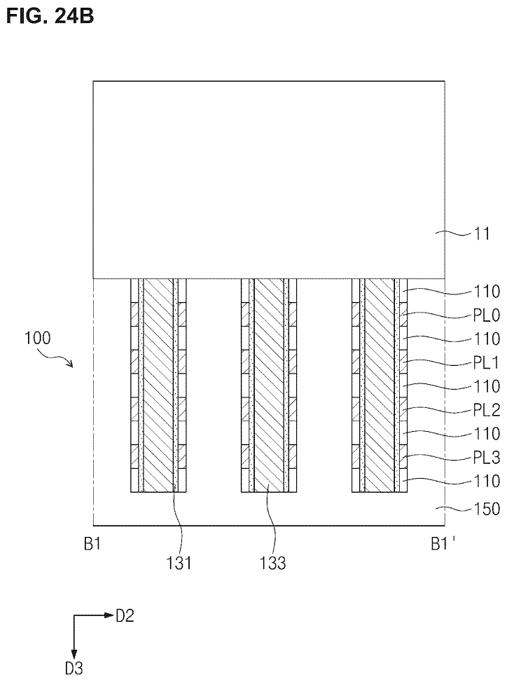

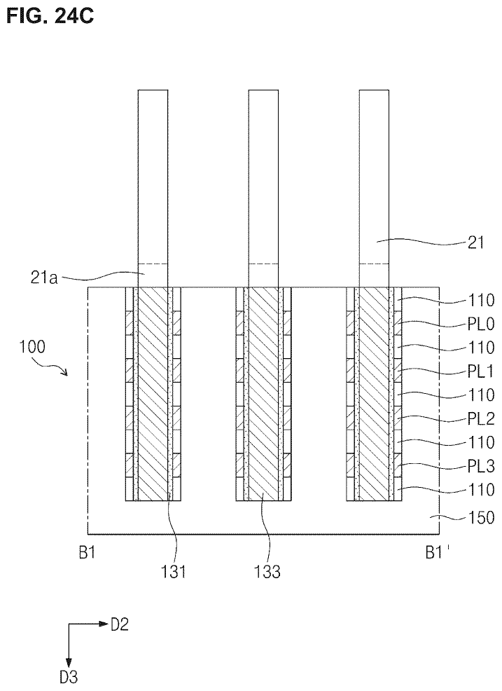

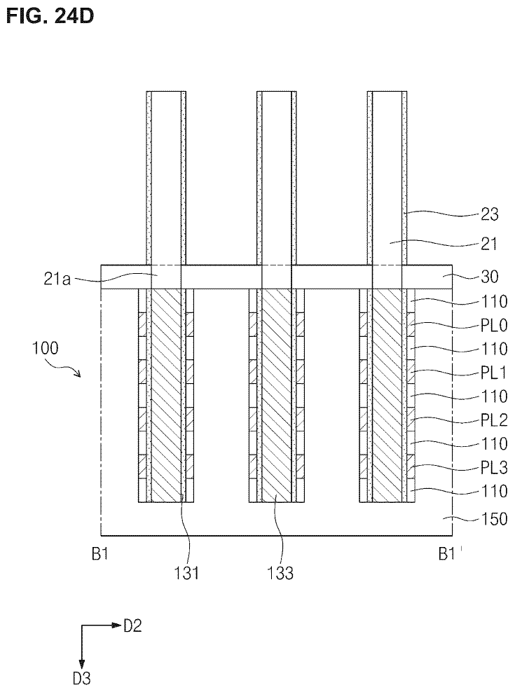

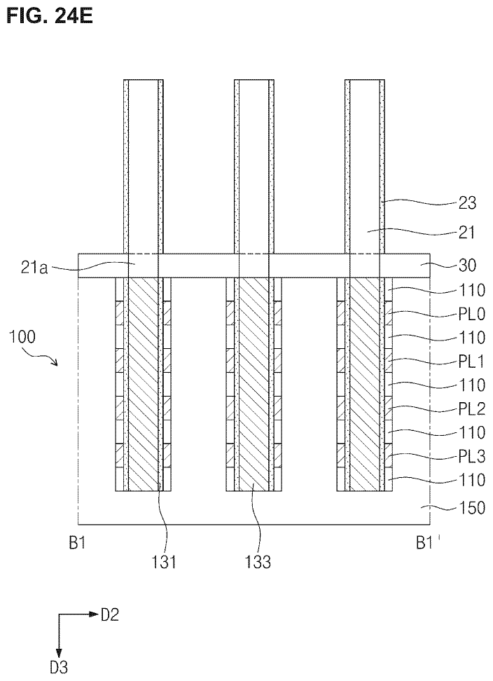

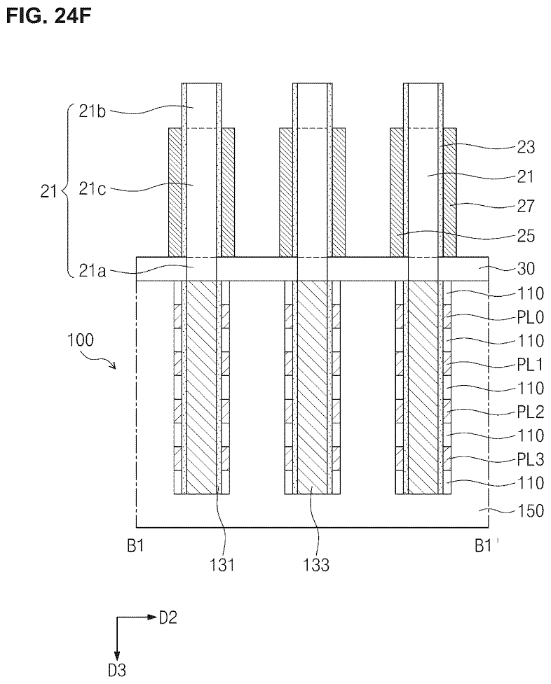

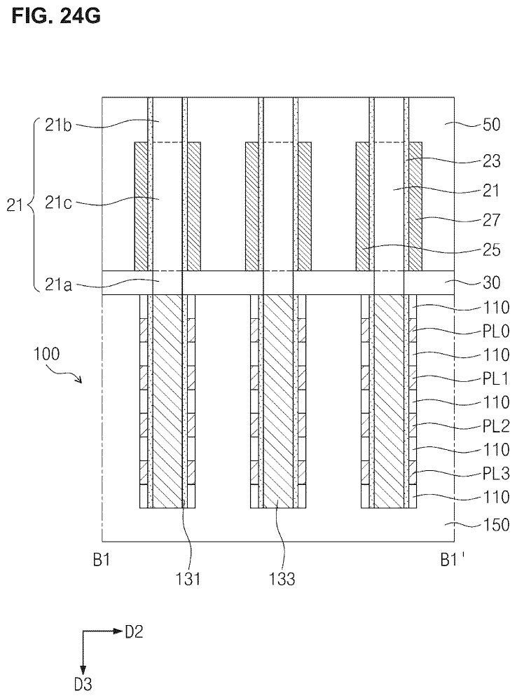

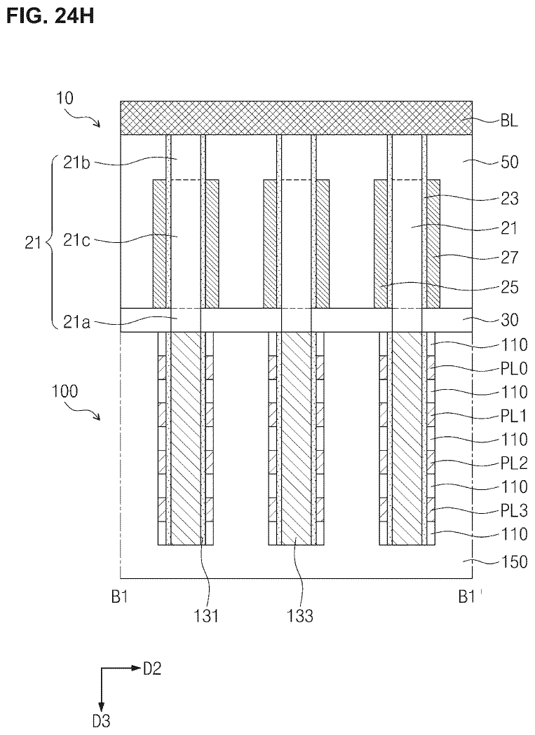

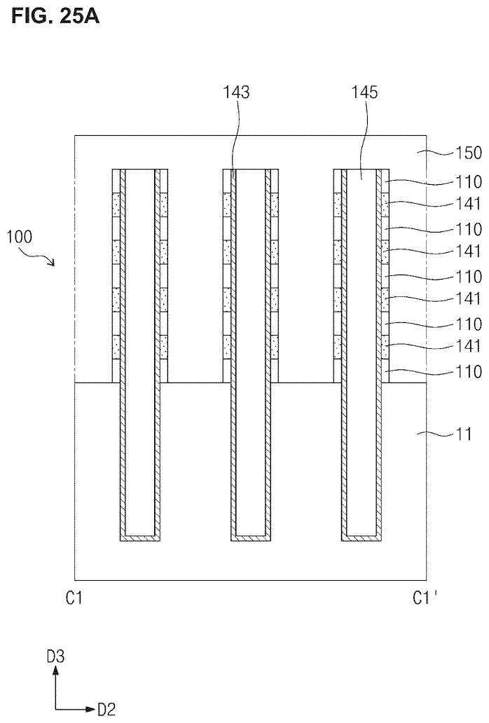

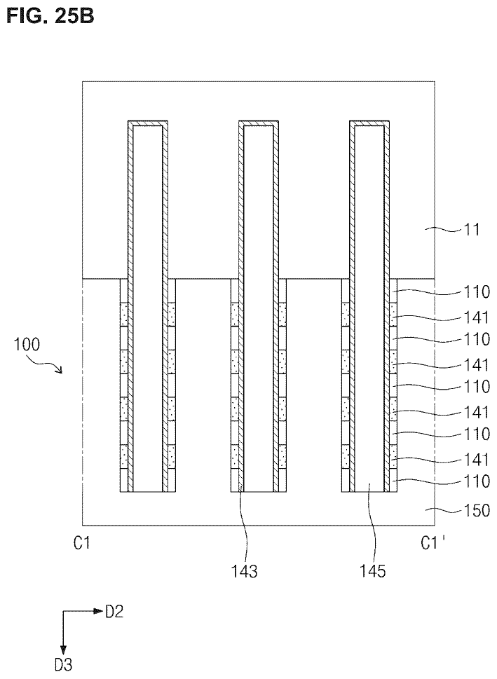

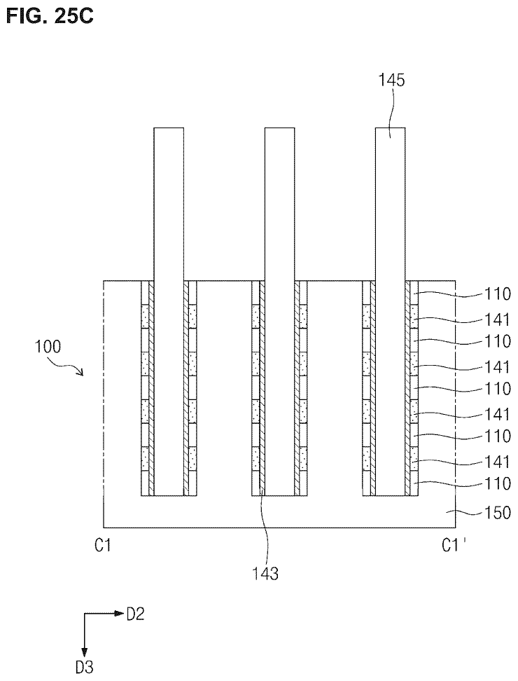

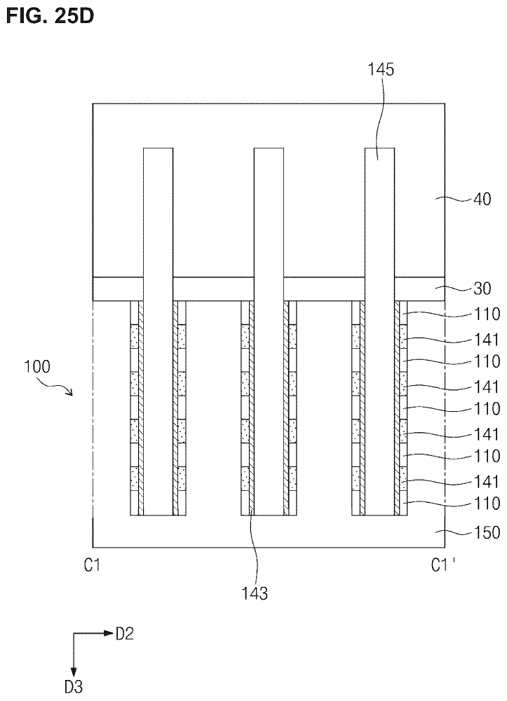

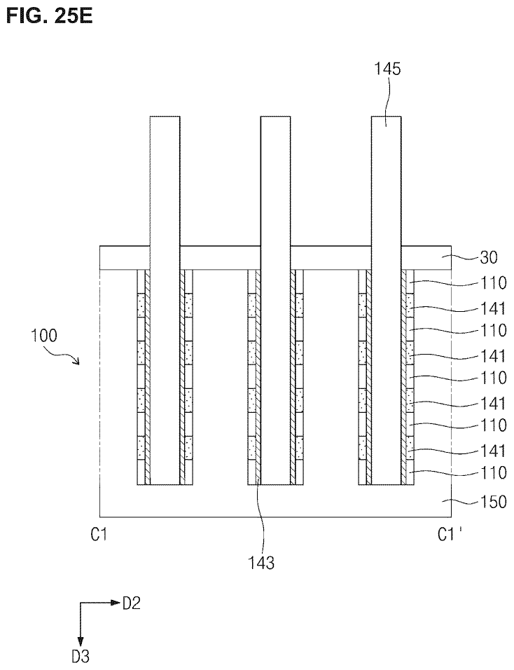

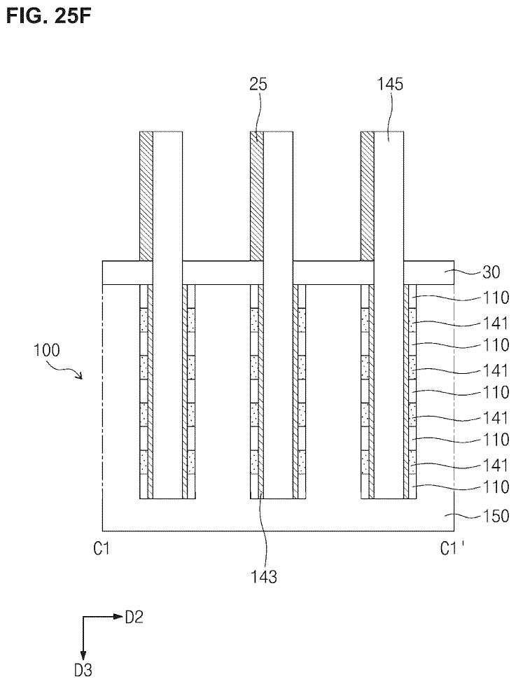

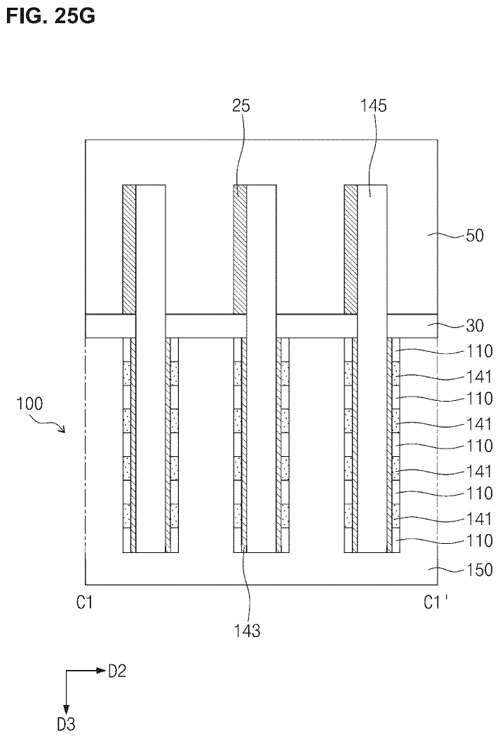

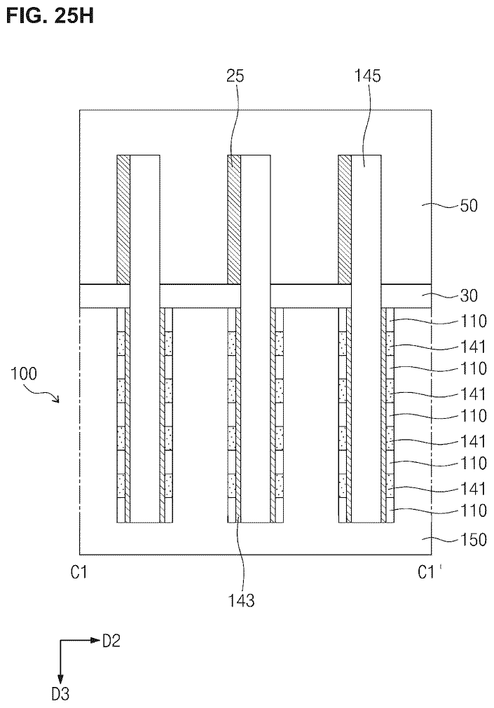

FIGS. 23A to 23H, 24A to 24H, and 25A to 25H are cross-sectional views sequentially illustrating a method of manufacturing the semiconductor device illustrated in FIGS. 21 and 22A to 22C. FIGS. 23A to 23H are cross-sectional views taken along line A2-A2′ of FIG. 21, FIGS. 24A to 24H are cross-sectional views taken along line B1-B1′ of FIG. 21, and FIGS. 25A to 25H are cross-sectional views taken along line C1-C1′ of FIG. 21.

Referring to FIGS. 23A, 24A, and 25A, a capacitor structure 100 may be formed on a substrate 11.

The substrate 11 may be, for example, a wafer. The wafer may include, for example, silicon (Si). The wafer may include a semiconductor element such as germanium (Ge), or a compound semiconductor such as silicon carbide (SiC), gallium arsenide (GaAs), indium arsenide (InAs), or indium phosphide (InP). According to some implementations, the wafer may have a silicon-on-insulator (SOI) structure. In some implementations, the substrate 11 may include a substate on which a series of processes for manufacturing a semiconductor device have been performed or are to be performed. In some implementations, the substrate 11 may include silicon.

When the capacitor structure 100 is formed, a selection gate electrode 145 may be formed to extend into the substrate 11. When the second trench TCH2 of FIG. 18D is formed, the second trench TCH2 may be formed to extend downward into the substrate 11 from the upper surface of the substrate 11 to form the selection gate electrode 145. Then, processes may be performed as illustrated in FIGS. 18E to 18N to form a capacitor structure 100 including the selection gate electrode 145 extending into the substrate 11.

Referring to FIGS. 23B, 24B, and 25B, the substrate 11 on which the capacitor structure 100 is formed may be flipped, and a process of forming a transistor structure may then be performed on the flipped substrate 11.

Referring to FIGS. 23C, 24C, and 25C, active pillars may be formed by patterning the substrate 11. The active pillars are provided for the semiconductor patterns 21 (see FIG. 21) of the access transistors. Hereinafter, for clarity, the active pillars used as semiconductor patterns 21 will be referred to as semiconductor patterns 21.

As illustrated in the drawings, the semiconductor patterns 21 and the selection gate electrodes 145 may be formed to different heights. A height of the semiconductor patterns 21 may be formed to be greater than a height of the selection gate electrodes 145.

In the operation of patterning the substrate 11, a selection gate insulating layer 143 surrounding the selection gate electrode 145 may be removed.

Referring to FIGS. 23D, 24D, and 25D, a second insulating layer 30 may be formed on the upper surface of the capacitor structure 100. The second insulating layer 30 may be formed on the upper surface of the capacitor structure 100, for example, on the first insulating layer 110. The second insulating layer 30 may cover a portion of the sides of the semiconductor patterns 21 and a portion of the sides of the capacitor electrodes 133.

A protective layer 40 may be formed on the second insulating layer 30 to cover the selection gate electrodes 145. The second insulating layer 30 may be formed only in a region in which the selection gate electrodes 145 are arranged, and may not be formed in a region in which the semiconductor patterns 21 are arranged.

Gate insulating layers 23 may be formed on the exposed sides of the semiconductor patterns 21. The gate insulating layers 23 may not be formed on the upper surfaces of the semiconductor patterns 21. However, in some implementations, the gate insulating layers 23 may remain on the upper surfaces of the semiconductor patterns 21.

In some implementations, impurities may be doped into a lower end portion of each semiconductor pattern 21. Accordingly, the first source/drain regions 21a of the semiconductor pattern 21 may be formed. However, the operation of doping impurities into the semiconductor patterns 21 is not limited thereto and may be performed in a different operation

Referring to FIGS. 23E, 24E, and 25E, the protective layer 40 covering the selection gate electrodes 145 may be removed. Due to the removal of the protective layer 40, a portion of the surface of the selection gate electrodes 145 may be exposed to the outside.

Referring to FIGS. 23F, 24F, and 25F, a first gate electrode 25 may be formed on one side of each semiconductor pattern 21 with a gate insulating layer 23 interposed therebetween. A second gate electrode 27 may be formed on another side of the semiconductor pattern 21 with a gate insulating layer 23 interposed therebetween. The first gate electrodes 25 may extend in the first direction D1 to be in contact with the selection gate electrodes 145. The second gate electrodes 27 may have a shorter length than the first gate electrodes 25, preventing contact with the selection gate electrodes 145.

In some implementations, impurities may be doped into an upper end portion of each semiconductor pattern 21. Accordingly, the second source/drain regions 21b of the semiconductor pattern 21 and the channel regions 21c between the first source/drain regions 21a and the second source/drain regions 21b may be formed. However, the operation of doping impurities into the semiconductor patterns 21 is not limited thereto and may be performed in a different operation.

Referring to FIGS. 23G, 24G, and 25G, a third insulating layer 50 is formed on the second insulating layer 30. The third insulating layer 50 may cover the first gate electrodes 25, the selection gate electrodes 145, and the exposed surfaces of the gate insulating layers 23. The third insulating layer 50 does not cover the second source/drain regions 21b of the semiconductor patterns 21 and the upper surfaces of the gate insulating layers 23, and thus, the second source/drain regions 21b of the semiconductor patterns 21 and the upper surfaces of the gate insulating layers 23 may be exposed to an external entity.

Referring to FIGS. 23H, 24H, and 25H, bitlines BL may be formed on the third insulating layer 50. The bitlines BL may be in contact with the exposed second source/drain regions 21b.

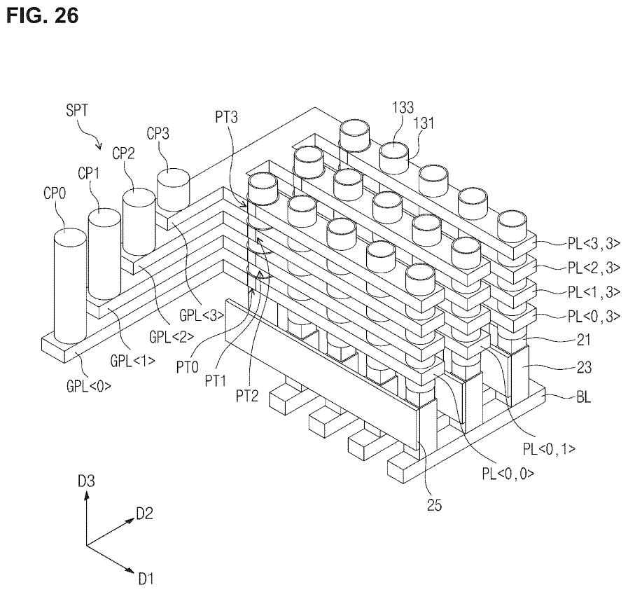

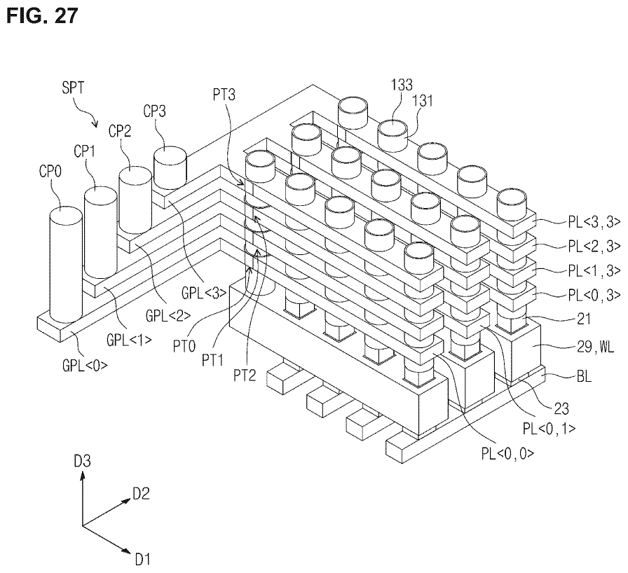

In some implementations, the access transistors may have various forms. FIGS. 26 and 27 are perspective views illustrating semiconductor devices according to some implementations, illustrating a case in which access transistors are provided in a different form from the above-described implementation.

Referring to FIG. 26, a capacitor structure 100 may be provided on a transistor structure 10. The capacitor structure 100 may be provided as one of the above-described implementation. In the drawings, the implementation illustrated in FIG. 16 is illustrated as an example.

The transistor structure 10 may include first gate electrodes 25 corresponding to wordlines WL, bitlines BL, semiconductor patterns 21, and gate insulating layers 23. The semiconductor patterns 21, the first gate electrodes 25, and the gate insulating layers 23 may form access transistors. In the present implementation, each access transistor is connected to a single first gate electrode 25, and a second gate electrode corresponding to a back gate electrode may not be provided.

Referring to FIG. 27, a transistor structure 10 may include all-around gate electrodes 29 corresponding to wordlines WL, bitlines BL, semiconductor patterns 21, and gate insulating layers 23. The semiconductor patterns 21, the all-around gate electrodes 29, and the gate insulating layers 23 may form access transistors.

Each of the gate insulating layers 23 may surround a corresponding semiconductor pattern 21 among the semiconductor patterns 21. Each of the all-around gate electrodes 29 may surround the semiconductor pattern 21 with each gate insulating layer 23 interposed therebetween. For example, each of the all-around gate electrode 29 may surround the channel region 21c of the corresponding semiconductor pattern 21.

As set forth above, a semiconductor device according to implementations, a cell array structure configured to significantly reduce the number of plate line pads or contact plugs may be provided. As a result, when the semiconductor device according to some implementations is applied, area efficiency of a three-dimensional ferroelectric memory may be improved.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various implementations have been illustrated and described above, it will be apparent to those skilled in the art that modifications and variations could be made without departing from the scope of the present disclosure as defined by the appended claims.

What is claimed is:

1. A semiconductor device comprising:
a transistor structure; and
a capacitor structure connected to the transistor structure,
wherein the capacitor structure comprises:
a plate line extending in a first direction,
a ferroelectric capacitor connected to the plate line,
a global plate line at a same level as the plate line, and
a plate line select transistor connected to the global plate line and the plate line, and
wherein the transistor structure comprises:
an access transistor comprising a gate connected to a wordline, a first end connected to the ferroelectric capacitor, and a second end connected to a bitline.

2. The semiconductor device of claim 1, wherein the ferroelectric capacitor comprises:
the plate line;
a capacitor electrode in a first trench, the first trench extending into the plate line; and
a ferroelectric layer between the plate line and the capacitor electrode.

3. The semiconductor device of claim 1, wherein the plate line select transistor comprises:
the plate line;
the global plate line;
a selection gate electrode in a second trench, the selection gate electrode being between the plate line and the global plate line;
a selection semiconductor pattern surrounding at least a portion of the selection gate electrode; and
a selection gate insulating layer between the selection gate electrode and the selection semiconductor pattern.

4. The semiconductor device of claim 3, wherein the capacitor structure comprises a plurality of plate lines including the plate line, and a plurality of global plate lines including the global plate line,
wherein the plurality of plate lines are arranged in a matrix in a second direction and a third direction, the first direction, the second direction, and the third direction being perpendicular to each other,
wherein the plurality of global plate lines are stacked in the third direction, and
wherein the plurality of global plate lines are at a same layer as respective plate lines, among the plurality of plate lines, that are arranged in a same row.

5. The semiconductor device of claim 4, wherein the capacitor structure comprises (i) a capacitor region containing the ferroelectric capacitor and (ii) a staircase region connected to the capacitor region and having a staircase shape.

6. The semiconductor device of claim 5, wherein, in the staircase region, the plurality of global plate lines are stacked in layers, and
wherein a length of each plurality of global plate line decreases from a lowermost layer to an uppermost layer or from an uppermost layer to a lowermost layer.

7. The semiconductor device of claim 5, wherein each of the capacitor region and the staircase region extends in the first direction or the second direction.

8. The semiconductor device of claim 5, wherein, in the staircase region, the plurality of global plate lines extend in a same direction as the plurality of plate lines.

9. The semiconductor device of claim 5, wherein, in the staircase region, the plurality of global plate lines extend in a direction perpendicular to an extension direction of the plurality of plate lines.

10. The semiconductor device of claim 5, comprising a plurality of plate line contact plugs with each plate line contact plug contacting an upper surface or a lower surface of a respective global plate line of the plurality of global plate lines in the staircase region.

11. The semiconductor device of claim 1, wherein the ferroelectric capacitor comprises a capacitor electrode, and
wherein the access transistor comprises:
a semiconductor pattern comprising a first end connected to the capacitor electrode and a second end connected to the bitline,
a gate electrode on at least one side of the semiconductor pattern, and
a gate insulating layer between the semiconductor pattern and the gate electrode.

12. The semiconductor device of claim 11, wherein the plate line select transistor comprises a selection gate electrode extending into the transistor structure,
wherein the gate electrode extends in a direction perpendicular to the selection gate electrode, and
wherein the selection gate electrode contacts the gate electrode at an intersection between the selection gate electrode and the gate electrode.

13. The semiconductor device of claim 11, wherein the gate electrode comprises a first gate electrode on a first side of the semiconductor pattern and a second gate electrode on a second side of the semiconductor pattern.

14. The semiconductor device of claim 13, wherein the second gate electrode is a back gate electrode and has a shorter length than the first gate electrode.

15. The semiconductor device of claim 11, wherein the gate electrode is an all-around gate electrode surrounding at least a portion of the semiconductor pattern.

16. The semiconductor device of claim 1, wherein the access transistor comprises at least one of a buried channel array transistor (BCAT), a planar transistor, a fin field-effect transistor (FinFET), or a multi-bridge channel field-effect transistor (MBCFET).

17. A capacitor structure comprising:
a plate line;
a ferroelectric capacitor connected to the plate line;
a global plate line at a same level as the plate line; and
a plate line select transistor connected to the global plate line and the plate line.

18. The capacitor structure of claim 17, wherein the plate line extends in a first direction and comprises a plurality of plate lines arranged in a matrix in a second direction and a third direction, the first direction, the second direction, and the third direction being perpendicular to each other,
wherein the global plate line comprises a plurality of global plate lines stacked in the third direction, and
wherein the global plate lines are at a same level as respective plate lines, among the plurality of plate lines, in a same row.

19. The capacitor structure of claim 17, wherein the ferroelectric capacitor comprises a ferroelectric layer, and
wherein the ferroelectric layer comprises at least one of lead zirconate titanate (PZT), strontium bismuth tantalate (SBT), bismuth lanthanum titanate (BLT), hafnium oxide, hafnium zirconium oxide, zirconium oxide, barium strontium titanium oxide, barium titanium oxide, or lead zirconium titanium oxide.

20. A semiconductor device comprising:
a cell array comprising a plurality of memory cells at intersections of a plurality of wordlines and a plurality of bitlines; and
an address decoder configured to transmit wordline signals and global plate line signals to the plurality of wordlines and a plurality of global plate lines,
wherein each of the plurality of memory cells comprises:
a plurality of plate lines,
a plurality of ferroelectric capacitors connected to the plurality of plate lines,
an access transistor comprising a gate connected to a wordline of the plurality of wordlines, a first end connected to a ferroelectric capacitor of the plurality of ferroelectric capacitors, and a second end connected to a bitline of the plurality of bitlines,
the global plate line, and
a plate line select transistor connecting the global plate line and the plate line.
